(19) United States
(12) Patent Application Publication
(10) Pub. No.: US 2025/0318273 A1
(43) Pub. Date: Oct. 9, 2025

(54) DIODE FORMATION WITH BACKSIDE POWER DELIVERY NETWORK

(71) Applicant: INTERNATIONAL BUSINESS MACHINES CORPORATION, ARMONK, NY (US)

(72) Inventors: Ruilong Xie, Niskayuna, NY (US); Robert Gauthier, Williston, VT (US); Anthony I-Chih Chou, Guilderland, NY (US); Tao Li, Slingerlands, NY (US)

(21) Appl. No.: 18/631,010

(22) Filed: Apr. 9, 2024

(51) Int. Cl. H01L 27/02; H01L 21/8234; H01L 23/528; H01L 27/06; H01L 27/088; H01L 29/06; H01L 29/08; H01L 29/66; H01L 29/861

(52) U.S. Cl. CPC H10D 89/60; H01L 23/5286; H10D 8/00; H10D 62/121; H10D 62/151; H10D 64/017; H10D 64/018; H10D 84/013; H10D 84/0149; H10D 84/038; H10D 84/811; H10D 84/83

(57) ABSTRACT

A semiconductor device includes a diode, the diode includes a first frontside contact over a first source/drain region, a first backside contact, and a first placeholder connected to a bottom surface of the first source/drain region.

### BACKGROUND

### Technical Field

The present disclosure generally relates to transistors, and more particularly, to diode devices with backside contact integrated with transistors, and methods of creation thereof.

### Description of the Related Art

In an integrated circuit (IC) with transistors and an electrostatic discharge (ESD) diode, transistors are used to perform active functions such as signal amplification and logic operations. An ESD diode is a protective device used in semiconductor and electronic circuits to route damaging electrostatic discharges away from sensitive components. An ESD diode provides a low resistance path from a circuit node to ground or the supply rail to safely dissipate static electric charges and prevent voltage spikes from reaching critical components. ESD diodes are designed to turn on and conduct electricity very quickly when a rapid voltage spike occurs, clamping the voltage to a safe level before damage happens.

### SUMMARY

According to an embodiment, a semiconductor device includes a diode, the diode including a first frontside contact over a first source/drain region, a first backside contact, and a first placeholder connected to a bottom surface of the first source/drain region.

In some embodiments, which can be combined with the previous embodiment, the semiconductor device includes a transistor, the transistor including a second frontside contact over a second source/drain region, a second backside contact, and a second placeholder connected to a bottom surface of the second source/drain region.

In some embodiments, which can be combined with one or more previous embodiments, the diode is an electrostatic discharge (ESD) diode.

In some embodiments, which can be combined with one or more previous embodiments, the transistor includes a plurality of nanosheet gates.

In some embodiments, which can be combined with one or more previous embodiments, the diode further includes a third source/drain region, and alternative layers of silicon and silicon germanium extended horizontally between the first source/drain region and the third source/drain region.

In some embodiments, which can be combined with one or more previous embodiments, the first source/drain region is an N-type source-drain region and the third source/drain region is a P-type source/drain region, or the first source/drain region is a P-type source-drain region and the third source/drain region is an N-type source/drain region.

In some embodiments, which can be combined with one or more previous embodiments, the diode further includes shallow trench isolation (STI), one or more additional placeholders, and a protective liner over the STI, the one or more additional placeholders, and portions of the diode that are not in direct contact with the first source/drain region and the third source/drain region.

In some embodiments, which can be combined with one or more previous embodiments, the protective liner is made of silicon nitride.

In some embodiments, which can be combined with one or more previous embodiments, the diode is adjacent to the transistor, and the diode and the transistor are separated by a dummy gate with an inner spacer.

According to an embodiment, a semiconductor device includes a diode, the diode including a first frontside contact over a first source/drain region, and a first placeholder connected to a bottom surface of the first source/drain region, and a logic device including a logic backside contact and a logic frontside contact.

In some embodiments, which can be combined with the previous embodiment, the diode is an electrostatic discharge (ESD) diode, and the logic device is a nanosheet transistor.

In some embodiments, which can be combined with one or more previous embodiments, the diode includes a second source/drain region, and alternative layers of silicon and silicon germanium extended horizontally between the first source/drain region and the second source/drain region.

In some embodiments, which can be combined with one or more previous embodiments, the first source/drain region is an N-type source-drain region and the second source/drain region is a P-type source/drain region, or the first source/drain region is a P-type source-drain region and the second source/drain region is an N-type source/drain region.

In some embodiments, which can be combined with one or more previous embodiments, the diode includes shallow trench isolation (STI), one or more additional placeholders, and a protective liner over the STI, the one or more additional placeholders, and portions of the diode that are not in direct contact with the first source/drain region and the second source/drain region.

In some embodiments, which can be combined with one or more previous embodiments, the diode is adjacent to the logic device, and the diode and the logic device are separated by a dummy gate with an inner spacer.

According to an embodiment, a method for forming a semiconductor device, includes forming a diode including forming a first source/drain region, forming a first frontside contact over the first source/drain region, forming a first backside contact, and forming a placeholder at a bottom surface of the first source/drain region.

In some embodiments, which can be combined with the previous embodiment, the method includes forming a transistor including forming a second source/drain region, forming a second frontside contact over the second source/drain region, forming a second backside contact, and forming a second placeholder at a bottom surface of the second source/drain region.

In some embodiments, which can be combined with one or more previous embodiments, the method includes forming a plurality of nanosheet gates extended horizontally along gate channels.

In some embodiments, which can be combined with one or more previous embodiments, the method includes forming a third source/drain region and forming alternative layers of silicon and silicon germanium extended horizontally between the first source/drain region and the third source/drain region.

In some embodiments, which can be combined with one or more previous embodiments, the method includes forming shallow trench isolation (STI), forming one or more additional placeholders, forming a protective liner over the STI, the one or more additional placeholders, and portions of the diode that are not in direct contact with the first source/drain region and the third source/drain region.

In some embodiments, which can be combined with one or more previous embodiments, the method includes isolating the diode and the transistor by a dummy gate with an inner spacer.

According to an embodiment, a method for forming a semiconductor device, includes forming a diode, including forming a first source/drain region, forming a first frontside contact over the first source/drain region, and a first placeholder connected to a bottom surface of the first source/drain region, and forming a logic device, including forming a logic backside contact, and forming a logic frontside contact.

In some embodiments, which can be combined with the previous embodiment, the method includes forming a second source/drain region, and forming alternative layers of silicon and silicon germanium extended horizontally between the first source/drain region and the second source/drain region.

In some embodiments, which can be combined with one or more previous embodiments, the method includes forming shallow trench isolation (STI), forming one or more additional placeholders, and forming a protective liner over the STI, the one or more additional placeholders, and portions of the diode that are not in direct contact with the first source/drain region and the second source/drain region.

In some embodiments, which can be combined with one or more previous embodiments, the method includes isolating the diode and the logic device by a dummy gate with an inner spacer.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments.

Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIGS. 1A-1D illustrate a semiconductor device, in accordance with some embodiments.

FIG. 1E illustrates a top view of the semiconductor depicting the cross-sections shown in each FIG.

FIGS. 2A-2D illustrate side-views of a semiconductor device after the patterning of the nanosheets, in accordance with some embodiments.

FIGS. 3A-3D illustrate side-views of a semiconductor device after the recession of the nanosheets, in accordance with some embodiments.

FIGS. 4A-4D illustrate side-views of a semiconductor device after the indentation of the silicon germanium layers, in accordance with some embodiments.

FIGS. 5A-5D illustrate side-views of a semiconductor device after the formation of the inner spacer, in accordance with some embodiments.

FIGS. 6A-6D illustrate side-views of a semiconductor device after the formation of the placeholders, in accordance with some embodiments.

FIGS. 7A-7D illustrate side-views of a semiconductor device after the formation of the source/drain regions, in accordance with some embodiments.

FIGS. 8A-8D illustrate side-views of a semiconductor device after the formation of the interlayer dielectric, in accordance with some embodiments.

FIGS. 9A-9D illustrate side-views of a semiconductor device after the removal of the dummy gates, in accordance with some embodiments.

FIGS. 10A-10D illustrate side-views of a semiconductor device after the removal of the silicon germanium layers, in accordance with some embodiments.

FIGS. 11A-11D illustrate side-views of a semiconductor device after the metallization of the gate channel, in accordance with some embodiments.

FIGS. 12A-12D illustrate side-views of a semiconductor device after the removal of the substrate, in accordance with some embodiments.

FIGS. 13A-13D illustrate side-views of a semiconductor device after the removal of the silicon germanium layer, in accordance with some embodiments.

FIGS. 14A-14D illustrate side-views of a semiconductor device after the backside interlayer dielectric, in accordance with some embodiments.

FIGS. 15A-15D illustrate side-views of a semiconductor device after the patterning of the backside contact, in accordance with some embodiments.

FIGS. 16A-16D illustrate side-views of a semiconductor device after the metallization of the backside contact, in accordance with some embodiments.

FIGS. 17A-17D illustrate side-views of a semiconductor device after the formation of the backside metal contact, in accordance with some embodiments.

FIG. 18 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

According to an embodiment, a semiconductor device includes a diode, the diode including a first frontside contact over a first source/drain region, a first backside contact, and a first placeholder connected to a bottom surface of the first source/drain region. The diode does not need any substrate remaining for backside contact integration with the logic device.

In some embodiments, which can be combined with the previous embodiment, the semiconductor device includes a transistor, the transistor including a second frontside contact over a second source/drain region, a second backside contact, and a second placeholder connected to a bottom surface of the second source/drain region. Thus, the semiconductor device can include a diode and a transistor integrated on a same chip.

In some embodiments, which can be combined with one or more previous embodiments, the diode is an electrostatic discharge (ESD) diode. Thus, the semiconductor device can include an ESD diode and a transistor integrated on a same chip.

In some embodiments, which can be combined with one or more previous embodiments, the transistor includes a plurality of nanosheet gates. Thus, the semiconductor device can be applicable to a nanosheet transistor integrated with a diode on a same chip.

In some embodiments, which can be combined with one or more previous embodiments, the diode further includes a third source/drain region, and alternative layers of silicon and silicon germanium extended horizontally between the first source/drain region and the third source/drain region. The existence of alternative layers of silicon and silicon germanium can increase the effective channel area.

In some embodiments, which can be combined with one or more previous embodiments, the first source/drain region is an N-type source-drain region and the third source/drain region is a P-type source/drain region, or the first source/drain region is a P-type source-drain region and the third source/drain region is an N-type source/drain region. Thus, the diode includes oppositely doped sides, which facilitates operation of the diode.

In some embodiments, which can be combined with one or more previous embodiments, the diode includes shallow trench isolation (STI), one or more additional placeholders, and a protective liner over the STI, the one or more additional placeholders, and portions of the diode that are not in direct contact with the first source/drain region and the third source/drain region. The protective liner covers the opposite side of the diode except where the first source/drain and the third source/drain region are located.

In some embodiments, which can be combined with one or more previous embodiments, the protective liner is made of silicon nitride. The silicon nitride can protect the underlying layers from damage during the fabrication processes.

In some embodiments, which can be combined with one or more previous embodiments, the diode is adjacent to the transistor, and the diode and the transistor are separated by a dummy gate with an inner spacer. The dummy gate and the inner spacer can ensure that shorting between the diode and the transistor is avoided.

According to an embodiment, a semiconductor device includes a diode, the diode including a first frontside contact over a first source/drain region, and a first placeholder connected to a bottom surface of the first source/drain region, and a logic device including a logic backside contact and a logic frontside contact. The diode does not need any substrate for backside contact integration with the logic device.

In some embodiments, which can be combined with the previous embodiment, the diode is an electrostatic discharge (ESD) diode, and the logic device is a nanosheet transistor. Thus, the semiconductor device can include an ESD diode and a transistor integrated on a same chip.

In some embodiments, which can be combined with one or more previous embodiments, the diode includes a second source/drain region, and alternative layers of silicon and silicon germanium extended horizontally between the first source/drain region and the second source/drain region. The existence of alternative layers of silicon and silicon germanium can increase the effective channel area.

In some embodiments, which can be combined with one or more previous embodiments, the first source/drain region is an N-type source-drain region and the second source/drain region is a P-type source/drain region, or the first source/drain region is a P-type source-drain region and the second source/drain region is an N-type source/drain region. Thus, the diode includes opposite-doped sides, to facilitate operation of the diode.

In some embodiments, which can be combined with one or more previous embodiments, the diode includes shallow trench isolation (STI), one or more additional placeholders, and a protective liner over the STI, the one or more additional placeholders, and portions of the diode that are not in direct contact with the first source/drain region and the second source/drain region. The protective liner covers the opposite side of the diode except where the first source/drain and the third source/drain region are located.

In some embodiments, which can be combined with one or more previous embodiments, the diode is adjacent to the logic device, and the diode and the logic device are separated by a dummy gate with an inner spacer. The dummy gate and the inner spacer can ensure that shorting between the diode and the transistor is avoided.

According to an embodiment, a method for forming a semiconductor device includes forming a diode including forming a first source/drain region, forming a first frontside contact over the first source/drain region, forming a first backside contact, and forming a placeholder at a bottom surface of the first source/drain region. The diode does not need any substrate remaining for backside contact integration with the logic device.

In some embodiments, which can be combined with the previous embodiment, the method includes forming a transistor including forming a second source/drain region, forming a second frontside contact over the second source/drain region, forming a second backside contact, and forming a second placeholder at a bottom surface of the second source/drain region. Thus, the semiconductor device can include a diode and a transistor integrated on a same chip.

In some embodiments, which can be combined with one or more previous embodiments, the method includes forming a plurality of nanosheet gates extended horizontally along gate channels. Thus, the semiconductor device can include a diode and a nanosheet transistor integrated on a same chip.

In some embodiments, which can be combined with one or more previous embodiments, the method includes forming a third source/drain region and forming alternative layers of silicon and silicon germanium extended horizontally between the first source/drain region and the third source/drain region. The existence of alternative layers of silicon and silicon germanium can increase the effective channel area.

In some embodiments, which can be combined with one or more previous embodiments, the method includes forming shallow trench isolation (STI), forming one or more additional placeholders, forming a protective liner over the STI, the one or more additional placeholders, and portions of the diode that are not in direct contact with the first source/drain region and the third source/drain region. The protective liner covers the opposite side of the diode except where the first source/drain and the third source/drain region are located.

In some embodiments, which can be combined with one or more previous embodiments, the method includes isolating the diode and the transistor by a dummy gate with an inner spacer. The dummy gate and the inner spacer can ensure that shorting between the diode and the transistor is avoided.

According to an embodiment, a method for forming a semiconductor device includes forming a diode including forming a first source/drain region, forming a first frontside contact over the first source/drain region, and a first placeholder connected to a bottom surface of the first source/drain region, and forming a logic device, including forming a logic backside contact, and forming a logic frontside contact. The diode does not need any substrate remaining for backside contact integration with the logic device.

In some embodiments, which can be combined with the previous embodiment, the method includes forming a second source/drain region, and forming alternative layers of silicon and silicon germanium extended horizontally between the first source/drain region and the second source/drain region. Thus, the semiconductor device can include a diode and a transistor integrated on a same chip.

In some embodiments, which can be combined with one or more previous embodiments, the method includes forming shallow trench isolation (STI), forming one or more additional placeholders, and forming a protective liner over the STI, the one or more additional placeholders, and portions of the diode that are not in direct contact with the first source/drain region and the second source/drain region. The protective liner covers the opposite side of the diode except where the first source/drain and the third source/drain region are located.

In some embodiments, which can be combined with one or more previous embodiments, the method includes isolating the diode and the logic device by a dummy gate with an inner spacer. The dummy gate and the inner spacer can ensure that shorting between the diode and the transistor is avoided.

The concepts herein relate to electrostatic discharge (ESD) diodes, which are protective devices used in semiconductor and electronic circuits to route damaging electrostatic discharges away from sensitive components. ESD diodes provide a low resistance path from a circuit node to ground or the supply rail to safely dissipate static electric charges and prevent voltage spikes from reaching critical components. Typically, ESD diodes are designed to turn on and conduct electricity very quickly when a rapid voltage spike occurs, clamping the voltage to a safe level before damage happens. Commonly used ESD diode types include silicon p-n junction diodes, avalanche diodes, and Schottky diodes. Such diodes have fast response times in the nanosecond range.

ESD diodes are physically small but can conduct large currents for short time periods, diverting current away from components that might otherwise be destroyed by discharge events. ESD diodes shunt ESD events to ground while normally not interfering with circuit operation. When no ESD event occurs, the ESD diodes present a high impedance path to ground. ESD diodes are commonly placed on the I/O pads of integrated circuits and across power supplies to protect sensitive internal circuitry from static discharge events.

Disclosed is a semiconductor device that includes a diode and a logic device. The semiconductor device offers a backside contact and a frontside contact in both the logic device and the diode, without the need for any residual substrate. Thus, the backside contact is integrated with the diode, and is directly contacting the base silicon material rather than through remaining substrate material. By fabricating the diode without any remnant substrate, the disclosed semiconductor device simplifies the integration scheme by removing the need to etch through, or otherwise penetrate the substrate, to make the backside contact. Achieving such a backside contact integration, enabled by complete substrate removal, allows tighter integration and reduces parasitic effects stemming from substrate interactions.

Accordingly, the teachings herein provide methods and systems of semiconductor device formation with a diode and a logic device. The techniques described herein may be implemented in a number of ways. Example implementations are provided below with reference to the following figures.

### Example Semiconductor Device with Co-Integrated Diode and Logic Device Structure

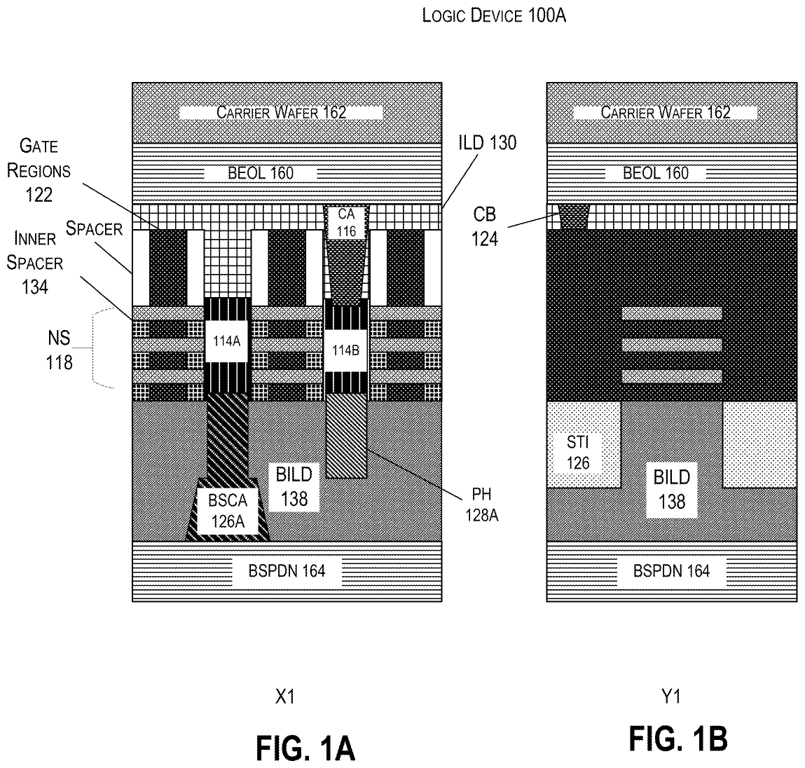

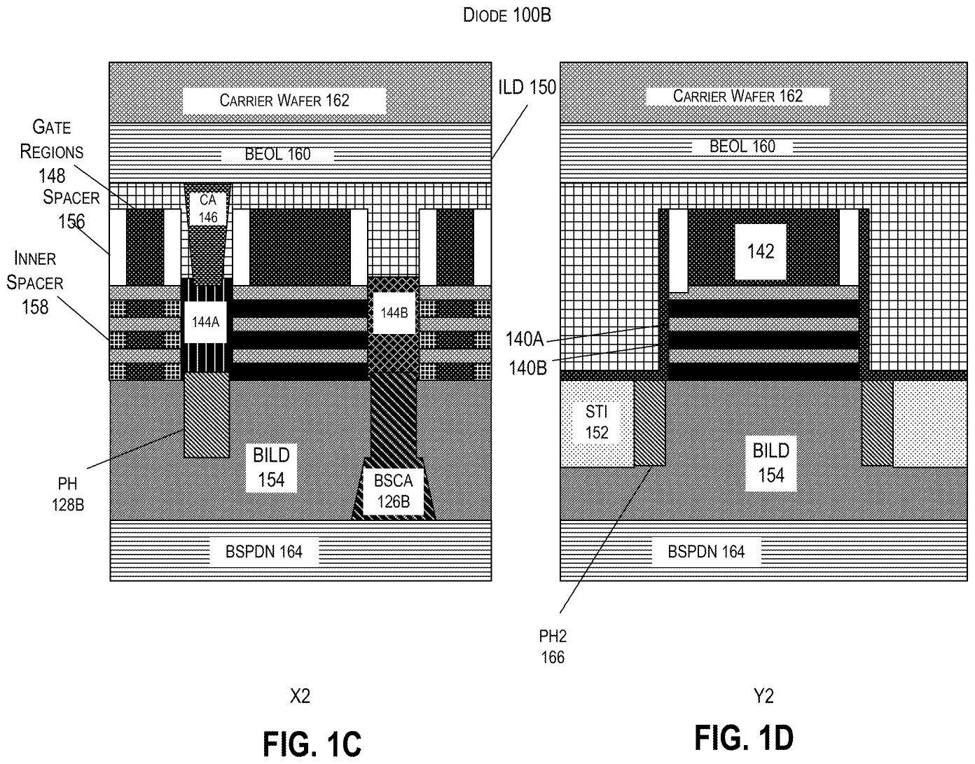

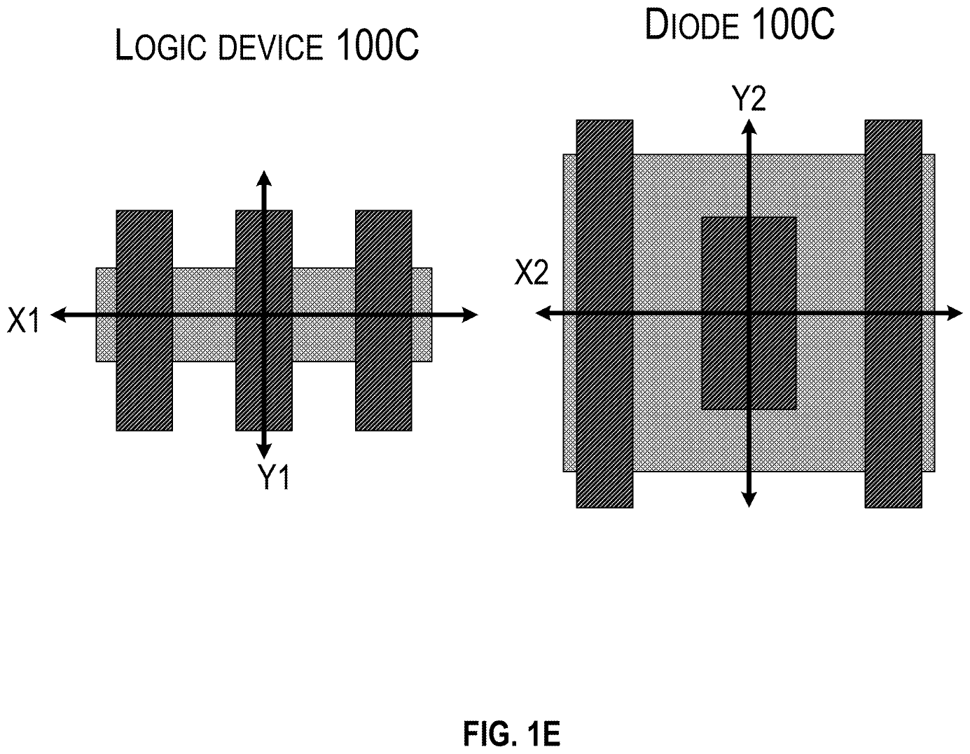

Reference now is made to FIGS. 1A-1D, which are simplified cross-sections view of a semiconductor device, consistent with an illustrative embodiment. In various embodiments, the semiconductor device includes a logic device 100A and a diode 100B. While for the sake of simplicity, the logic device 100A and the diode 100B are depicted separately, it should be noted that the logic device 100A and the diode 100B can be integrated on a same semiconductor device adjacent to each other. Moreover, and to avoid crowded drawings, the logic device 100A is shown in FIGS. 1A-1B, and the diode 100B is shown separately in FIGS. 1C-1D. FIG. 1E depicts a top-view of the semiconductor device showing different cross-sections from which FIGS. 1A-1D illustrate the semiconductor device.

Referring to FIGS. 1A-1B now, the logic device 100A can be a transistor. The transistor depicted in FIGS. 1A-1B is a nanosheets transistor. However, one skilled in the art would understand that the transistor can be any other transistor. The logic device 100A can include a first source/drain region 114A, a second source/drain region 114B, a source/drain contact, CA 116, a set of nanosheets, NS 118, a first backside contact, BSCA 126A, and a first placeholder, PH 128A. The logic device 100A further includes gate regions 122, a gate contact, CB 124, shallow trench isolation, STI 126, a bottom dielectric layer, BILD 138, an interlayer dielectric, ILD 130, a spacer 132, and an inner spacer 134.

Generally, the first source/drain region 114A and the second source/drain region 114B the are salient components that play relevant roles in the logic device 100A operation. In various embodiments, the first source/drain region 114A and the second source/drain region 114B are regions within the semiconductor material, e.g., the logic device 100A, where the current flows in and out of the logic device 100A. The source region is the region through which the majority of charge carriers (e.g., electrons or holes) enter the channel of the logic device 100A and is responsible for providing the current that flows through the logic device 100A. The source region is typically doped to have an excess of charge carriers, creating a region with high carrier concentration. This abundance of carriers allows for the efficient injection of electrons or holes into the channel when a voltage is applied.

The drain region, on the other hand, is the region where the majority of charge carriers exit the channel. The drain region receives the current from the channel and carries the charge away from the transistor. Similar to the source, the drain region is also doped to have a high carrier concentration. The doping profile in the drain region ensures that carriers can easily flow out of the channel and into the drain region.

In some embodiments, the first source/drain region 114A is connected to a frontside of the logic device 100A via the CA 116. In some embodiments, gate regions 122 are connected to the frontside of the logic device 100A via the CB 124. In an embodiment, the second source/drain region 114B is connected to the backside of the logic device 100A via the BSCA 126A.

The CA 116, located over the first source/drain region 114A, establishes a connection between the first source/drain region 114A and the BEOL 160. The CA 116 ensures efficient electrical routing and connectivity within the logic device 100A. The fabrication of the CA 116 can involve lithography and etching processes to define the contact area. The CA 116 can be made using conductive materials such as a silicide liner, e.g., Ni, Ti, NiPt, an adhesion metal layer, e.g., TiN and conductive metal fill material, e.g., tungsten (W), Co, or Ru.

The BSCA 126A is a region on the backside of the logic device 100A where electrical connections are made. By establishing the electrical contacts, the BSCA 126A ensures the proper functioning of the logic device 100A and facilitates electrical signal transmission.

The BSCA 126A can serve as a thermal interface between the logic device 100A and a heat sink or other cooling mechanisms. By establishing direct contact with the substrate, the BSCA 126A can conduct the heat away from the logic device 100A, and contribute to improved thermal dissipation. In some embodiments, the BSCA 126A can help mitigate parasitic effects, such as substrate coupling or substrate noise, from the logic device 100A. In further embodiments, the BSCA 126A can allow for increased integration density in the logic device 100A. In an embodiment, the BSCA 126A connects, e.g., wires, the first source/drain region 114A to the BSPDN 164.

In various embodiments, the gate regions 122 serve as control elements that regulate the flow of current through the logic device 100A. The gate regions 122 can be composed of a conductive material. The gate regions 122 can control the flow of electric current between the source and drain regions. In some embodiments, by applying a voltage to the gate, the channel region's conductivity is modulated, allowing the logic device 100A to either allow or block the flow of current, which in turn enables the logic device 100A to act as electronic switches or amplifiers. The gate voltage can determine whether the logic device 100A is in an “on” or “off” state. When the gate voltage is below a certain threshold, the logic device 100A is in the “off” state, and the current flow between the source and drain is effectively blocked. On the other hand, when the gate voltage exceeds the threshold, the logic device 100A enters the “on” state, allowing current to flow through the channel region. In addition to acting as a switch, modulating the gate voltage can enable the gate regions 122 to control the current flowing through the channel region, resulting in amplified output signals.

In an embodiment, the gate regions 122 can enable the implementation of Boolean logic operations, such as AND, OR, and NOT, by controlling the flow of current based on the input voltages. Multiple semiconductor devices can be interconnected to form complex logic circuits, enabling the execution of various computational tasks in digital systems. In some embodiments, the gate regions 122, along with other semiconductor device components, can facilitate the miniaturization and integration of electronic circuits. The ability to control the channel region's conductivity through the gate voltage allows for compact and highly efficient circuit designs.

The NS 118 includes 3D structures where the channel region of the logic device 100A is surrounded by multiple stacked nanosheets. The NS 118 serves as the conducting channels within the logic device 100A, and the gate structure controls the flow of current through these sheets.

The ILD 130 can be a layer of insulating material to electrically isolate and provide mechanical support between different layers of conducting and active components. The ILD 130 can enable efficient signal transmission, reduce crosstalk, and ensure the proper functioning of the logic device 100A. In an embodiment, the ILD 130 can electrically isolate adjacent conducting layers or active components in the logic device 100A. By providing insulation between different layers, the ILD 130 can prevent electrical shorts, reduce (e.g., minimize) leakage current, and ensure that signals are directed only along the desired pathways. In some embodiments, the ILD 130 can help reduce parasitic capacitance between adjacent metal interconnects or active devices and provide mechanical support to the logic device 100A structure.

The BILD 138 can be an insulating material or layer used to isolate and provide electrical insulation between the logic device 100A active regions and the BSCA 126A, and to prevent unwanted electrical contact between the active regions and the backside contact, ensuring the proper functioning and integrity of the logic device 100A. In various embodiments, the BILD 138 can function as a protective layer, shielding the active regions of the logic device 100A from external contaminants, moisture, and mechanical stress. The BILD 138 can further help prevent physical damage, such as scratches or particle contamination, which could adversely affect semiconductor device performance. Additionally, the BILD 138 can function as a barrier against moisture ingress, which can cause corrosion and degradation of the logic device 100A components.

Reference is now made to FIGS. 1C-1D, which illustrate the diode 100B of a semiconductor device, according to some embodiments. The diode 100B includes vertically stacked epitaxial layers of a first material 140A and a second material 140B, a protective liner 142, an N-type doped section 144A, a P-type doped section 144B, a second placeholder 128B, one or more additional placeholders, PH2 166, a contact 146, a second backside contact, BSCA 126B, and a set of gate regions 148. The diode further includes an ILD 150, STI 152, BILD 154, a spacer 156, and an inner spacer 158. The semiconductor device can further include a back end of line, BEOL 160, a carrier wafer 162, and a backside power delivery network, BSPDN 164.

The vertically stacked epitaxial layers of a first materials 140A and a second material 140B can include silicon as the first material 140A and silicon germanium as the second material 140B. The presence of such an electrically conductive stack multilayer can enhance the effective area of the channel region which can in turn improve the overall efficiency of the diode 100B.

The protective liner 142 can protect the underlying elements, such as the vertically stacked epitaxial layers of a first materials 140A and a second material 140B, the PH2 166, and the STI 152, from possible damage during the fabrication process. In other words, while the two opposite sides of the vertically stacked epitaxial layers of a first materials 140A and a second material 140B in X2 cut, as shown in FIG. 1C, are covered by the N-type doped section 144A and the P-type doped section 144B, respectively, the other two opposite sides of the vertically stacked epitaxial layers of a first materials 140A and a second material 140B in Y2 cut, as shown in FIG. 1D, are covered by the protective liner 142.

The N-type doped section 144A and the P-type doped section 144B form a p-n junction of the diode 100B. The junction allows current to flow in one direction (forward biased) but blocks current flow in the reverse direction up to a certain reverse breakdown voltage. The N-type doped section 144A includes an N-type semiconductor region with a high concentration of electrons. In other words, the N-type doped section 144A includes a region where the majority of charge carriers are electrons. In some embodiments, in order to increase the electron density, a large number of donor impurities, e.g., phosphorus or arsenic, are added to the region, which turns the region into an N+ region.

The P-type doped section 144B includes a P-type semiconductor region with a high concentration of holes. In some embodiments, in order to create the P-type doped section 144B, a high concentration of acceptor impurities, e.g., boron or aluminum, is introduced into the semiconductor material.

In some embodiments, the N-type doped section 144A is connected to a frontside of the diode 100B via the contact 146. In some embodiments, the set of gate regions 148 are connected to the frontside of the diode 100B via the contact 146. In an embodiment, the P-type doped section 144B is connected to the backside of the diode 100B via the BSCA 126B.

The contact 146, located over the N-type doped section 144A, establishes a connection between the N-type doped section 144A and the BEOL 160. The contact 146 ensures efficient electrical routing and connectivity within the diode 100B. The fabrication of the contact 146 can involve lithography and etching processes to define the contact area. The contact 146 can be made using conductive materials such as a silicide liner, e.g., Ni, Ti, NiPt, an adhesion metal layer, e.g., TiN and conductive metal fill material, e.g., tungsten (W), Co, or Ru.

The BSCA 126B is a region on the backside of the diode 100B where electrical connections are made. By establishing the electrical contacts, the BSCA 126B ensures the proper functioning of the diode 100B and facilitates electrical signal transmission.

The BSCA 126B can serve as a thermal interface between the diode 100B and a heat sink or other cooling mechanisms. By establishing direct contact with the substrate, the BSCA 126B can conduct the heat away from the diode 100B, and contribute to improved thermal dissipation. In some embodiments, the BSCA 126B can help mitigate parasitic effects, such as substrate coupling or substrate noise, from the diode 100B. In further embodiments, the BSCA 126B can allow for increased integration density in the diode 100B. In an embodiment, the BSCA 126B connects, i.e., wires, the P-type doped section 144B to the BSPDN 164.

In various embodiments, the set of gate regions 148 can serve as control elements that regulate the flow of current through the diode 100B. The set of gate regions 148 can be composed of a conductive material. The set of gate regions 148 can control the flow of electric current between the P-type doped section 144B and the N-type doped section 14A. In some embodiments, by applying a voltage to the gate, the channel region's conductivity is modulated, allowing the diode 100B to either allow or block the flow of current, which in turn enables the diode 100B to act as electronic switches or amplifiers. The gate voltage can determine whether the diode 100B is in an “on” or “off” state. When the gate voltage is below a certain threshold, the diode 100B is in the “off” state, and the current flow between the N-type doped section 144A and P-type doped section 144B is effectively blocked. On the other hand, when the gate voltage exceeds the threshold, the diode 100B enters the “on” state, allowing current to flow through the channel region. In addition to acting as a switch, modulating the gate voltage can enable the gate regions 122 to control the current flowing through the channel region, resulting in amplified output signals.

The ILD 150 can be a layer of insulating material to electrically isolate and provide mechanical support between different layers of conducting and active components. The ILD 150 can enable efficient signal transmission, reduce crosstalk, and ensure the proper functioning of the diode 100B. In an embodiment, the ILD 150 can electrically isolate adjacent conducting layers or active components in the diode 100B. By providing insulation between different layers, the ILD 150 can prevent electrical shorts, reduce (e.g., minimize) leakage current, and ensure that signals are directed only along the desired pathways. In some embodiments, the ILD 150 can help reduce parasitic capacitance between adjacent metal interconnects or active devices and provide mechanical support to the diode 100B structure.

The BILD 154 can be an insulating material or layer used to isolate and provide electrical insulation between the diode 100B active regions and the BSCA 126B, and to prevent unwanted electrical contact between the active regions and the backside contact, ensuring the proper functioning and integrity of the diode 100B. In various embodiments, the BILD 154 can function as a protective layer, shielding the active regions of the diode 100B from external contaminants, moisture, and mechanical stress. The BILD 154 can further help prevent physical damage, such as scratches or particle contamination, which could adversely affect semiconductor device performance. Additionally, the BILD 154 can function as a barrier against moisture ingress, which can cause corrosion and degradation of the diode 100B components.

The BEOL 160 includes metal interconnects, e.g., wires and metal lines, and insulating layers that connect the various components of the logic device 100A and enable them to function as a cohesive unit.

In some embodiments, the BSPDN 164 is formed and covers the BSCA 126A and the BILD 154. The BSPDN 164 can connect the logic device 100A to other devices. In some embodiments, the backside of the diode 100B and the backside of the logic device 100A are directly in contact with the BSPDN 164 via the BILD 138.

### Example Manufacture of a Semiconductor Device with Co-Integrated Diode and Logic Device

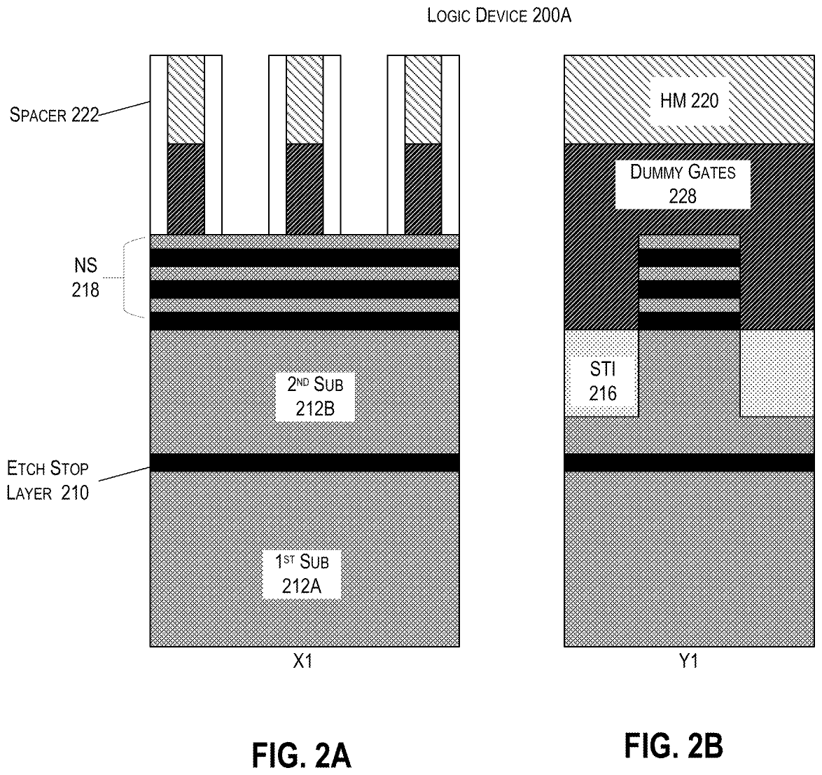

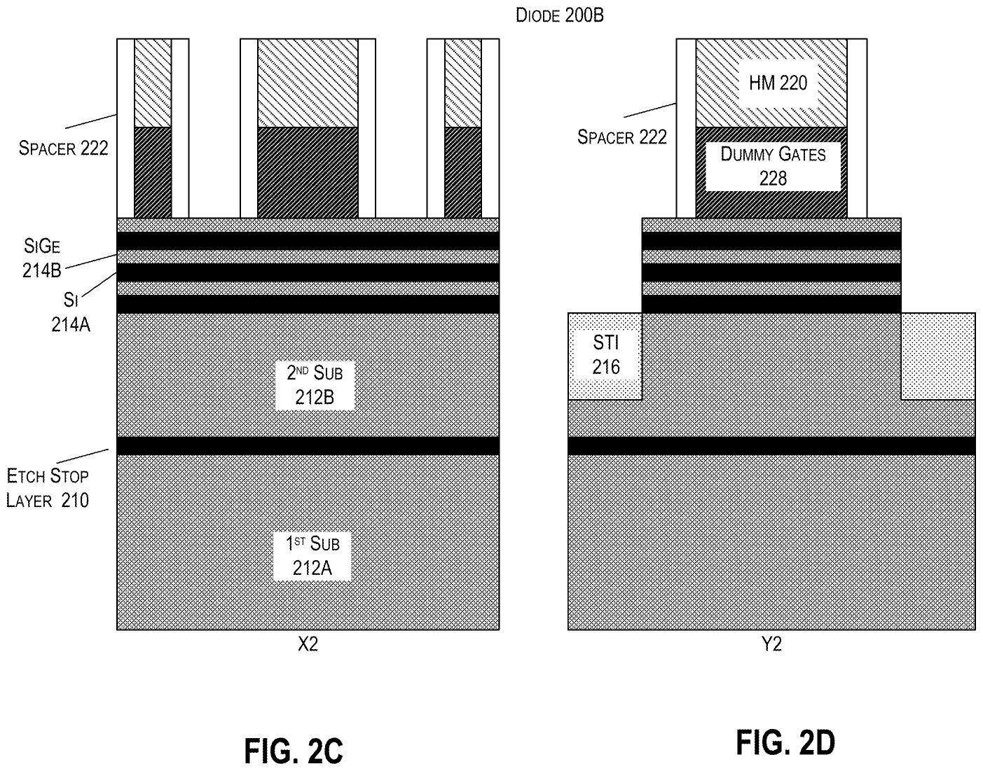

With the foregoing description of an example semiconductor device, it may be helpful to discuss an example act of manufacturing the same. To that end, FIGS. 2-17 illustrate various acts in the manufacture of a semiconductor device, consistent with illustrative embodiments. Figures denoted by A, illustrate an X1 section of the logic device, and figures denoted by B, illustrate a Y1 section of the logic device in reference to FIG. 1E. Similarly, figures denoted by C illustrate an X2 section of the diode, and figures denoted by D illustrate a Y2 section of the diode in reference to FIG. 1E. It is also worth mentioning that the semiconductor device depicted in FIGS. 1A-1D can be the same as the semiconductor device depicted in FIGS. 2-17. For ease of illustration, the fabrication acts depicted therein will be described in the context of forming a nanosheet transistor as the logic device, while it will be understood that other semiconductor structures are supported by the teachings herein as well.

Referring now is made to FIGS. 2A-2D, which illustrates a semiconductor device after the patterning of the nanosheets, in accordance with some embodiments. In some embodiments, after the patterning of the nanosheet, NS 218, the logic device 200A and the diode 200B include a first substrate 212A, a second substrate 212B, an etch stop layer 210 between the first substrate 212A and the second substrate 212B, vertically stacked epitaxial layers silicon, Si 214A, and silicon-germanium, SiGe 214B, STI 216, dummy gates 228, hard masks, HM 220, and a spacer 222.

In the illustrative example depicted in FIGS. 2A-2D, the semiconductor device is depicted as being on silicon as the first substrate 212A and the second substrate 212B, while it will be understood that other types as substrates may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the first substrate 212A and the second substrate 212B may include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

In various embodiments, the etch stop layer 210 is formed over the first substrate 212A. The etch stop layer 210 can be a thin layer of material incorporated into the structure of the semiconductor device to provide a selective barrier against etching processes, preventing further removal of underlying materials during fabrication. The etch stop layer 210 can enable precise control over the etching depth and help define the desired device dimensions. The etch stop layer 210 can further provide a stopping point for the etching process, ensuring that specific layers or regions are not etched beyond a certain point, leading to accurate patterning and control of critical features. The etch stop layer 210 can create a distinct separation between different layers or components within the device structure, and prevent the undesired etching of underlying layers or materials, enabling the creation of complex, multi-layered structures with well-defined interfaces and boundaries. In some embodiments, the etch stop layer 210 acts as a protective barrier for sensitive or delicate materials to shield such materials from aggressive etchants, preventing damage or degradation during subsequent fabrication steps.

In some embodiments, prior to forming the etch stop layer 210, the first substrate 212A is prepared by cleaning and removing any impurities or oxide layers. The etch stop layer 210 is deposited onto the first substrate 212A using techniques such as chemical vapor deposition (CVD), physical vapor deposition (PVD), or atomic layer deposition (ALD). In an embodiment, a photoresist can be applied, exposed to a patterned mask, developed, and used as a protective layer to define the etch stop regions. The etch stop layer 210 can then be selectively etched, stopping at a predetermined depth, while protecting the underlying layers. After the etching process, the remaining photoresist can be removed through stripping techniques. While in some embodiments, SiGe is used to form the etch stop layer 210, in some embodiments, silicon nitride (SiN), silicon oxide (SiO2), or silicon oxynitride (SiON) can be used as the etch stop layer 210. In some embodiments, a second substrate 212B is epitaxially grown over the etch stop layer 210.

In various embodiments, the vertically stacked epitaxial layers of Si 214A and SiGe 214B in Y1 and Y2 cross-sections of the logic device 200A and the diode 200B, depicted in FIG. 2B and FIG. 2D, respectively, is extended horizontally over the second substrate 212B. In other words, the vertically stacked epitaxial layers of Si 214A and SiGe 214B do not cover the STI 216.

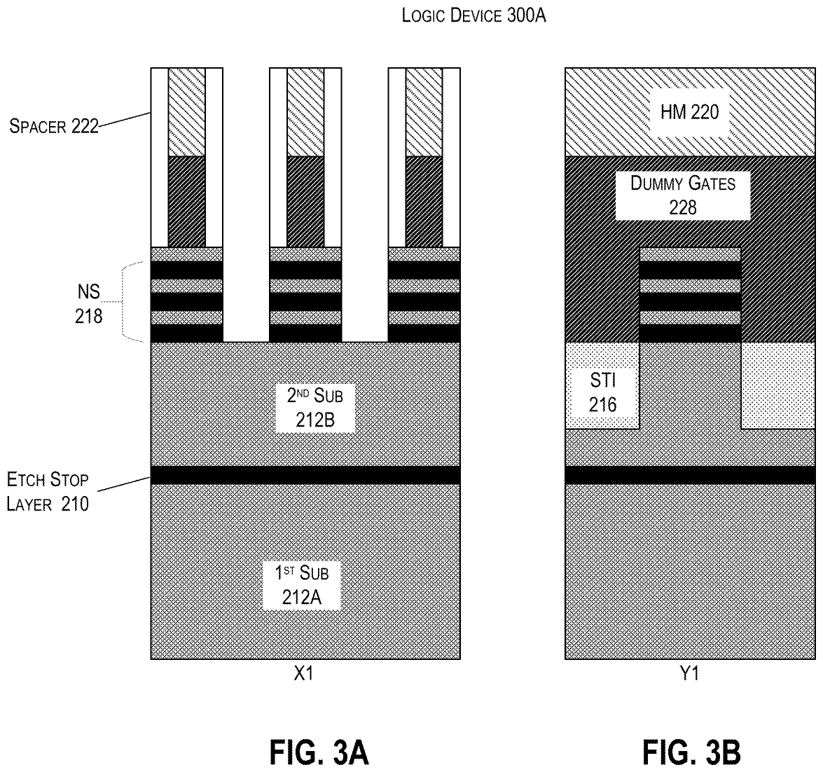

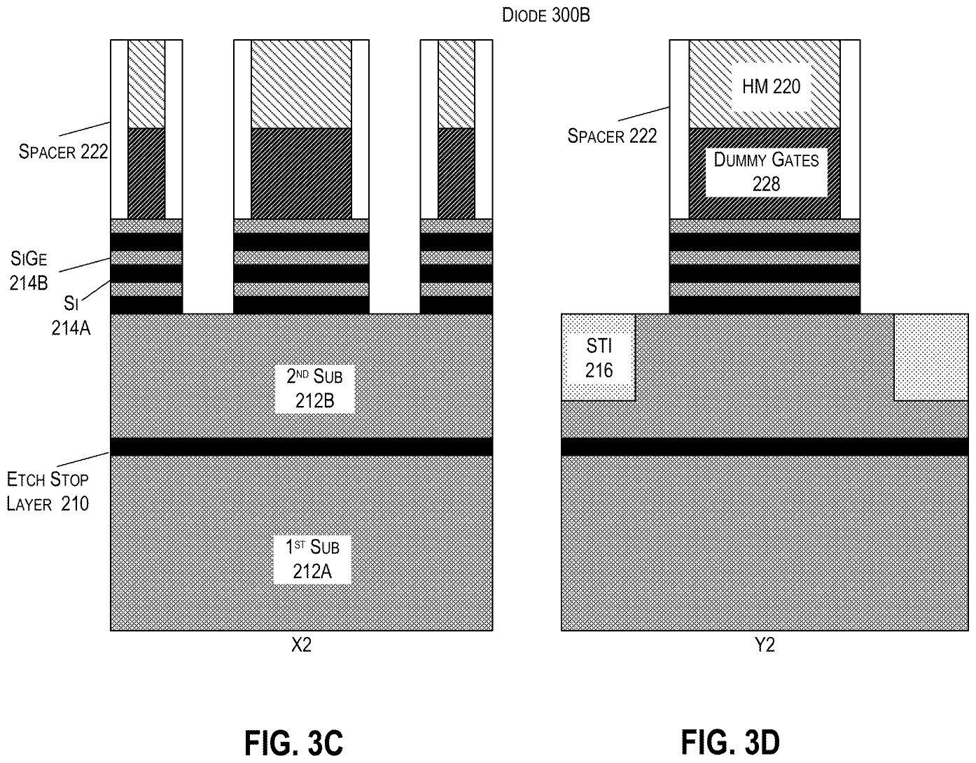

FIGS. 3A-3D illustrate the semiconductor device, including the logic device 300A and the diode 300B, after recession of the nanosheets, in accordance with some embodiments. In some embodiments, the NS 218 can be recessed, so the surface of the second substrate 212B is exposed. It should be noted that, the portions of the logic device 300A covered by the HM 220, i.e., Y1 cross-section, remain intact, as shown by FIG. 3B.

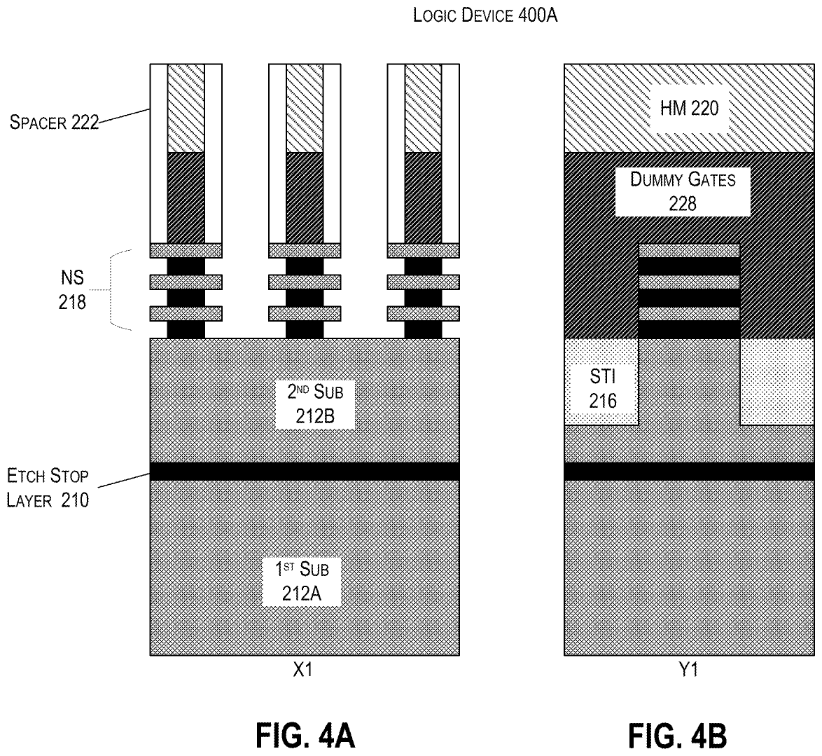

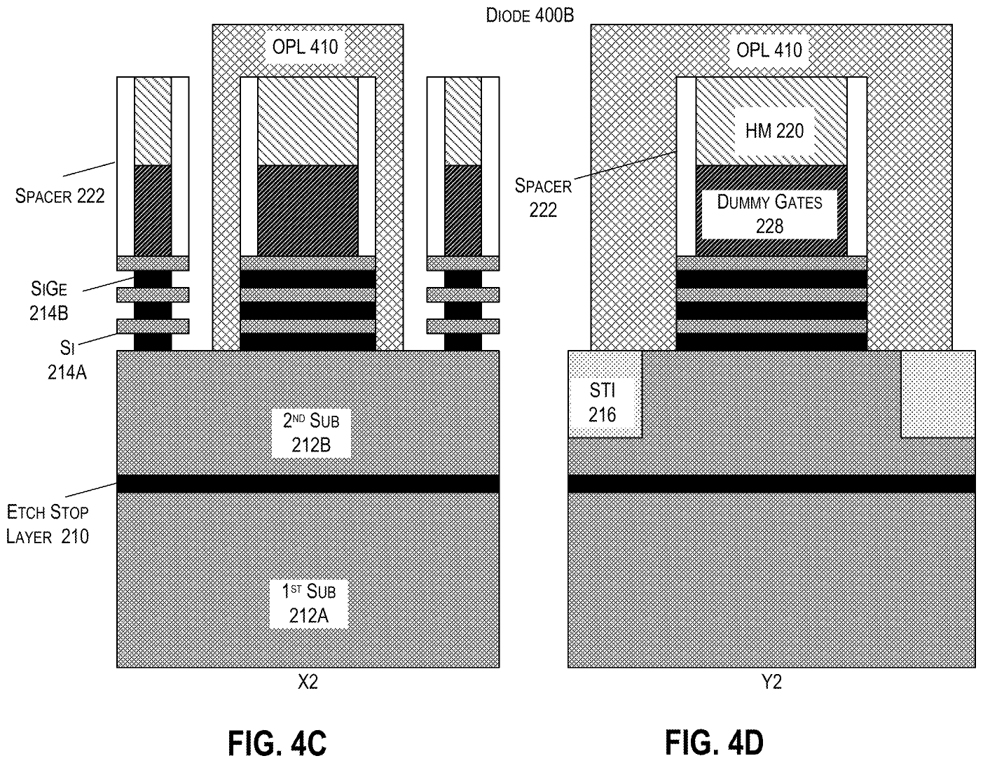

FIGS. 4A-4D illustrate the semiconductor device, including the logic device 400A and the diode 400B, after the indentation of the silicon germanium layer, in accordance with some embodiments. In some embodiments, an organic planarization layer, OPL 410, is formed over the gate vertically stacked epitaxial layers of Si 214A and SiGe 214B of the diode 400B. The OPL 410 can protect the underlying elements from fabrication processes. Afterwards, the silicon germanium layers of the vertically stacked epitaxial layers of Si 214A and SiGe 214B are in indented, e.g., etched, by a suitable method.

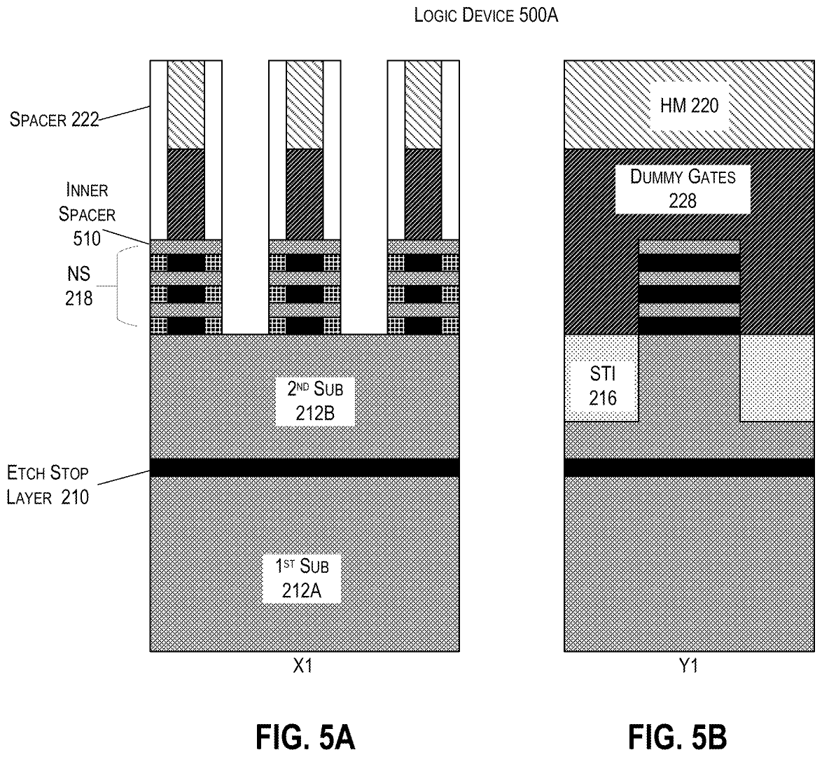

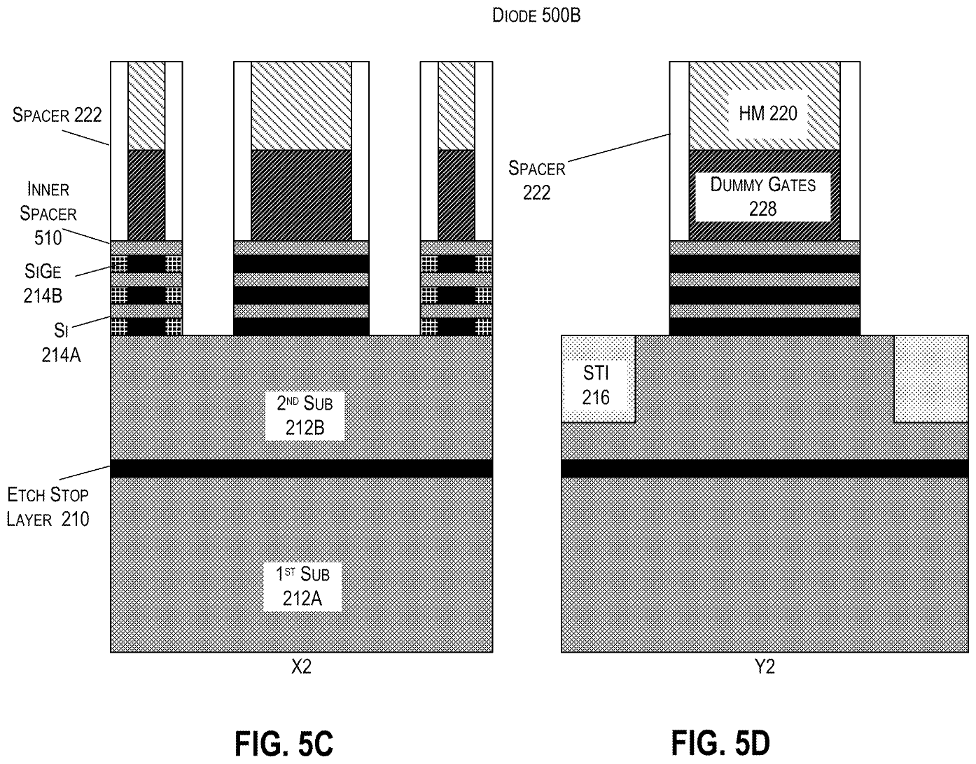

FIGS. 5A-5D illustrate the semiconductor device, including the logic device 500A and the diode 500B, after the formation of the inner spacer, in accordance with some embodiments. In some embodiments, an inner spacer 510 is formed between each two adjacent layers of Si 214A and SiGe 214B in the logic device 500A and the diode 500B. In various embodiments, the OPL is removed.

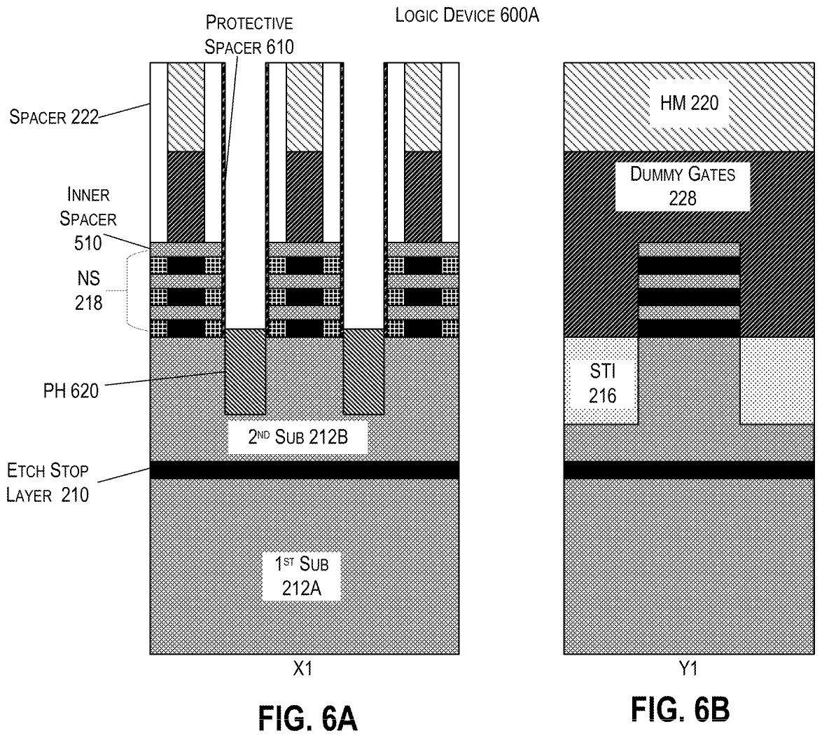

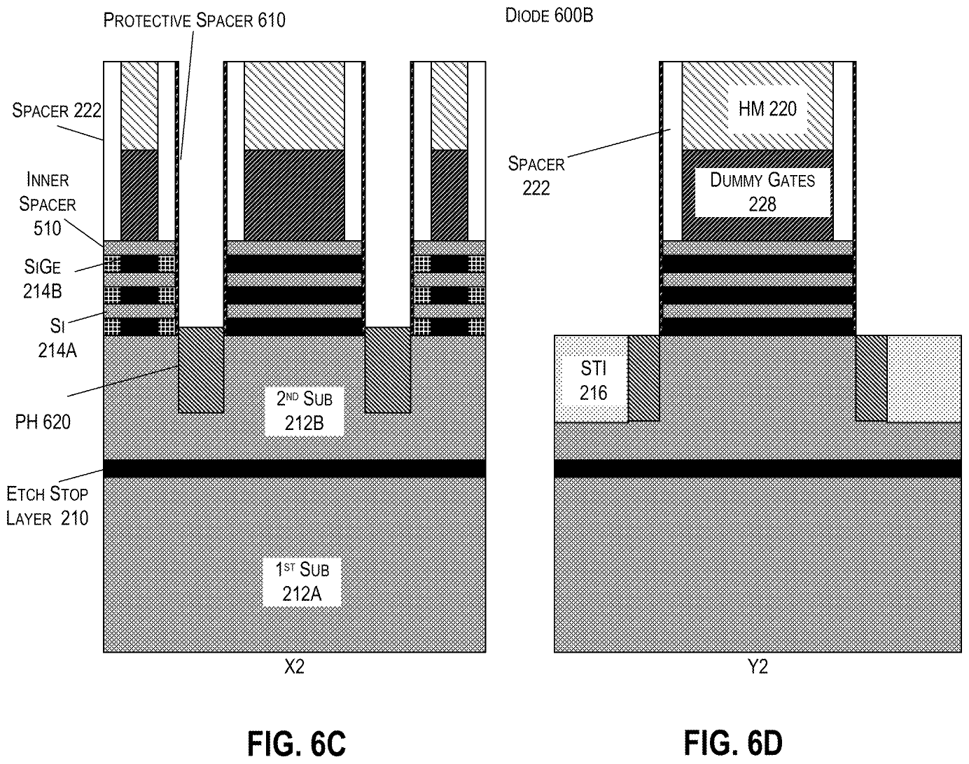

FIGS. 6A-6D illustrate the semiconductor device, including the logic device 600A and the diode 600B, after the formation of the placeholder, in accordance with some embodiments. In some embodiments, a protective spacer 610 is formed over sidewalls of the cavity between the gate regions. Afterwards, portions of the second substrate 212B are removed and placeholders 620 are formed in the recessed portions. The portions of the second substrate 212B can be removed by a reactive ion etching (RIE) technique. Generally, RIE is a dry etching process used in semiconductor device fabrication to remove materials from the surface of a substrate selectively. In some embodiments, RIE can involve the use of reactive ions and plasma to react with and remove specific materials chemically. In an embodiment, the RIE process begins by placing the semiconductor device inside a vacuum chamber. The chamber is then evacuated to create a low-pressure environment. Reactive gases, which can include a combination of a chemically reactive gas and an inert gas, are introduced into the chamber. The chemically reactive gas, such as fluorine-based gases (e.g., CF4, SF6) or chlorine-based gases (e.g., Cl2), can react with the material to be etched, i.e., the second substrate, Si, while the inert gas, e.g., argon, can help to control the ion bombardment.

In some embodiments, radiofrequency or microwave power is applied to create a plasma within the chamber. In such embodiments, power excites the gas molecules, causing them to ionize and form a plasma of reactive ions and electrons. The plasma can include reactive ions that chemically react with the silicon. The reactive ions bombard the substrate surface, break chemical bonds and remove silicon. In various embodiments, the RIE process can be selective, meaning it can mainly affect the target material, i.e., silicon, while leaving other materials, such as masking layers or underlying layers, relatively unaffected.

In some embodiments, to achieve selective etching, an etch mask can be applied on the substrate surface prior to the RIE process. The etch mask protects certain regions from etching, allowing the reactive ions to remove the exposed material selectively. The etching process can be controlled to achieve specific etch profiles, such as vertical sidewalls or tapered structures. Parameters such as gas composition, pressure, power, and process duration are adjusted to achieve the desired etch characteristics. In some embodiments, endpoint detection techniques, such as optical emission spectroscopy or laser interferometry, can be used to determine when the etching process has reached a desired endpoint. This ensures accurate control of the etch depth and prevents over-etching. After the etching process is completed, the substrate can be cleaned to remove any residue or by-products from the etching. Cleaning can involve rinsing with solvents or plasma cleaning to ensure the substrate's surface is free from contaminants. Subsequently, the removed portions of the second substrate 212B can be filled with the placeholders 620. The placeholders 620 can be epitaxially grown.

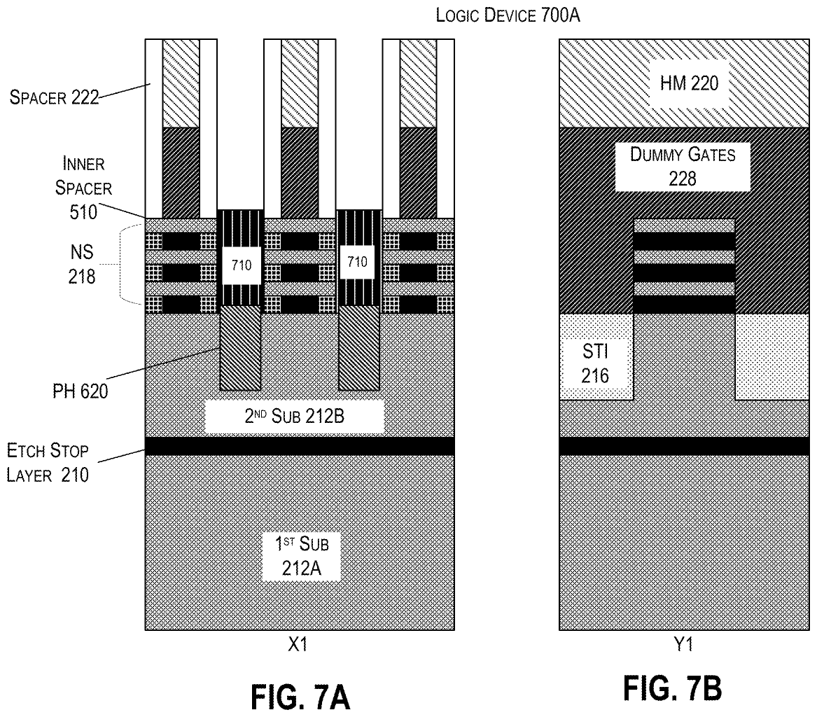

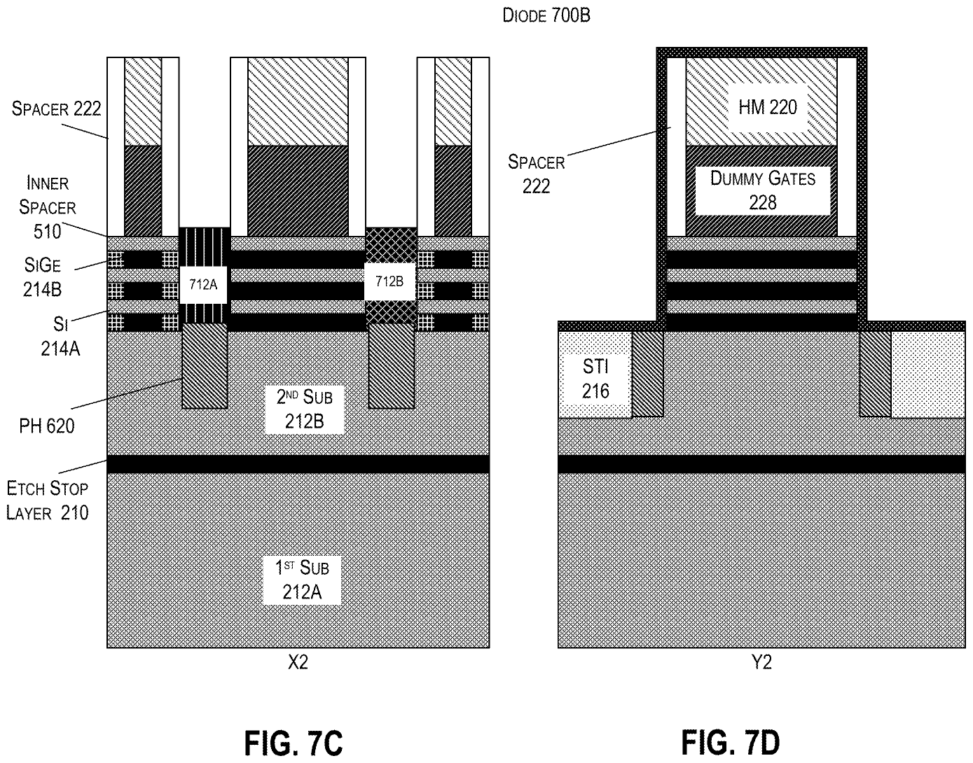

FIGS. 7A-7D illustrate the semiconductor device, including the logic device 700A and the diode 700B, after the formation of the source/drain regions, in accordance with some embodiments. In some embodiments, the source/drain regions 710 are formed above the placeholders 620 in the logic device 700A. Similarly, an N-type doped section 712A and a P-type doped section 712B are formed over the placeholders 620 in the diode 700B. Prior to the formation of the source/drain regions 710, the N-type doped section 712A and the P-type doped section 712B, and in order to preserve the vertically stacked epitaxial layers of Si 214A and SiGe 214B which are not in contact with the N-type doped section 712A and the P-type doped section 712B, a protective liner 720, e.g., silicon nitride, covers the vertically stacked epitaxial layers of Si 214A and SiGe 214B in the diode 700B which are not in contact with the N-type doped section 712A and the P-type doped section 712B in the diode 700B. The protective liner 720 can cover the STI 216 and the additional placeholders 740 that are not in contact with the N-type doped section 712A and the P-type doped section 712B in the diode 700B.

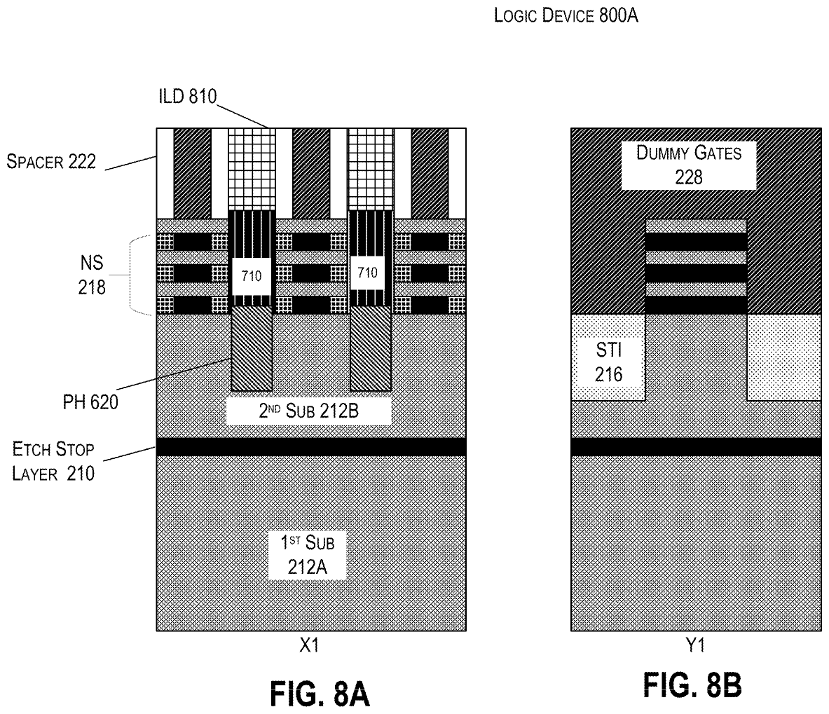

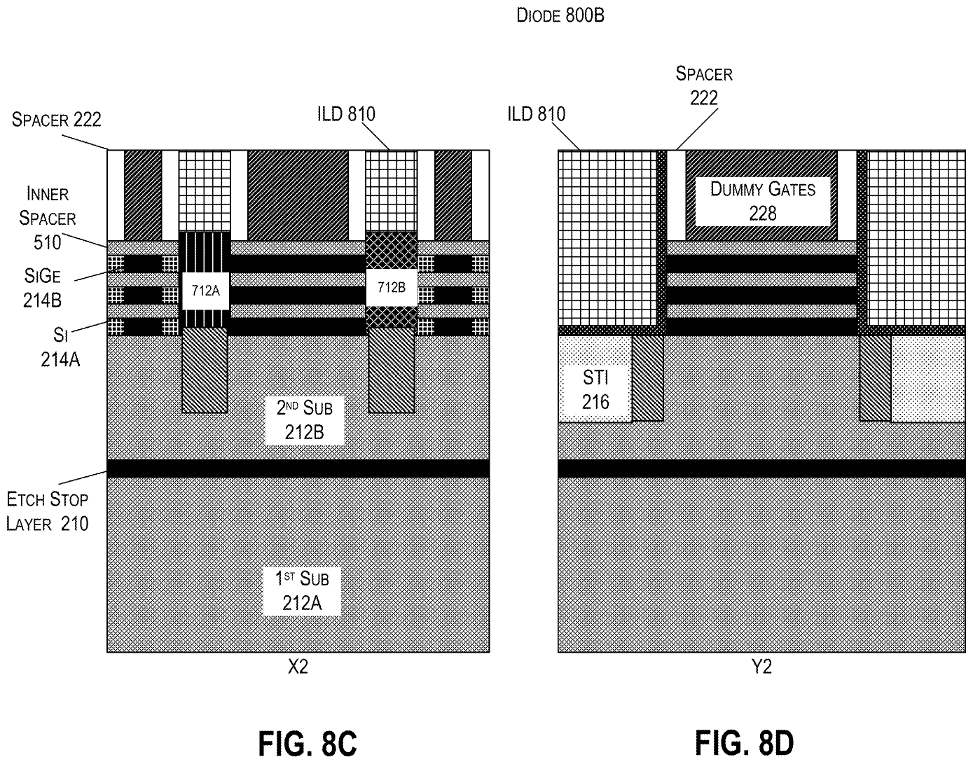

FIGS. 8A-8D illustrate the semiconductor device, including the logic device 800A and the diode 800B, after the formation of the interlayer dielectric, in accordance with some embodiments. In some embodiments, the interlayer dielectric, ILD 810, is formed over the source/drain regions 710 in the logic device 800A, and over the N-type doped section 712A and the P-type doped section 712B, and the protective liner 720 in the diode 800B.

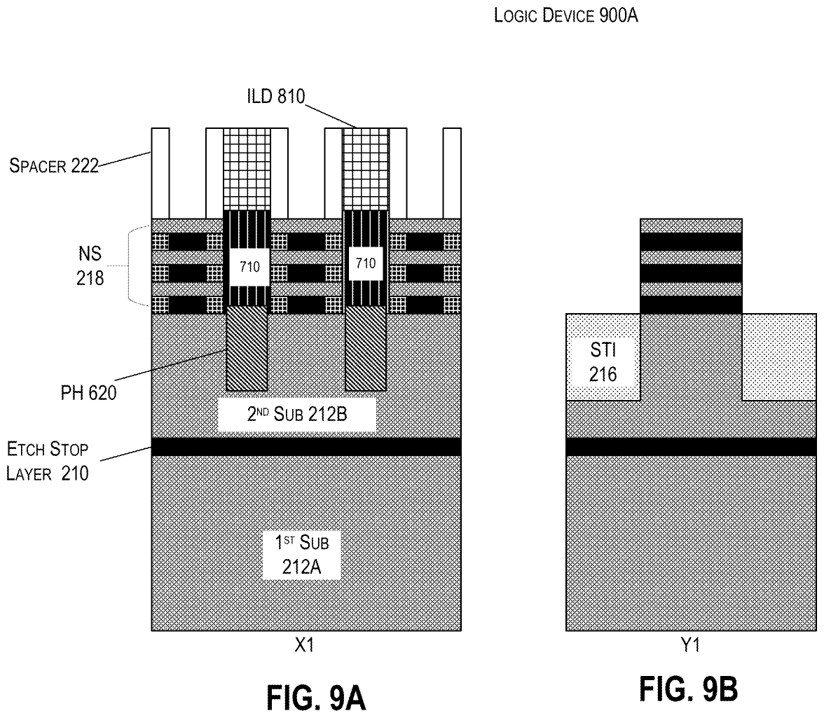

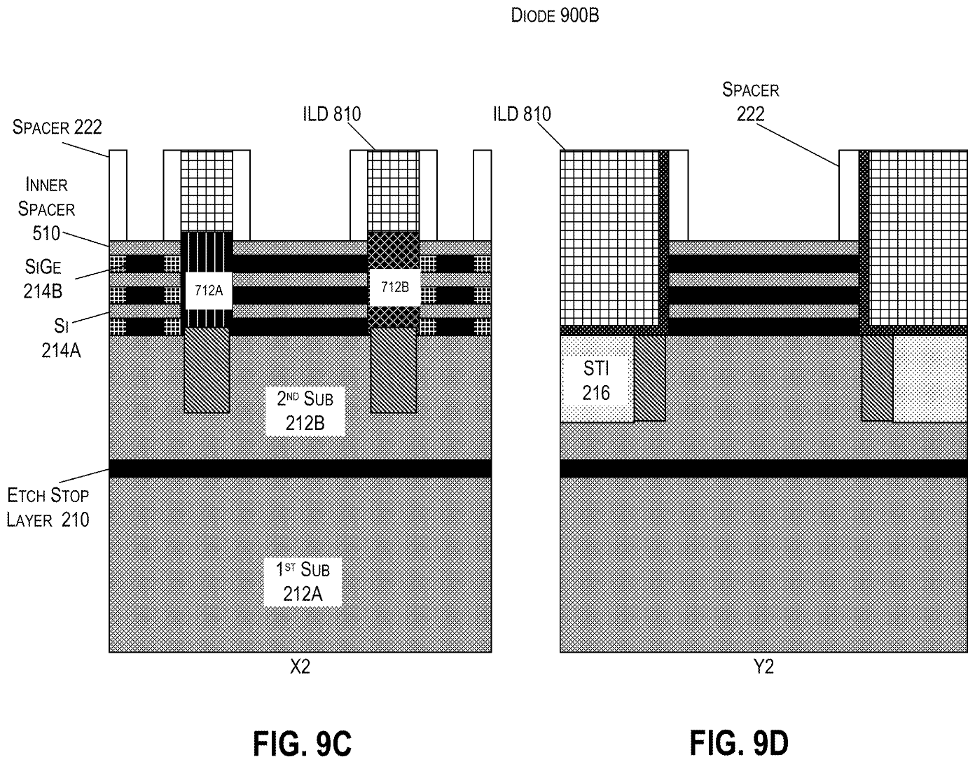

FIGS. 9A-9D illustrate the semiconductor device, including the logic device 900A and the diode 900B, after the removal of the dummy gates, in accordance with some embodiments. In some embodiments, the dummy gates are removed.

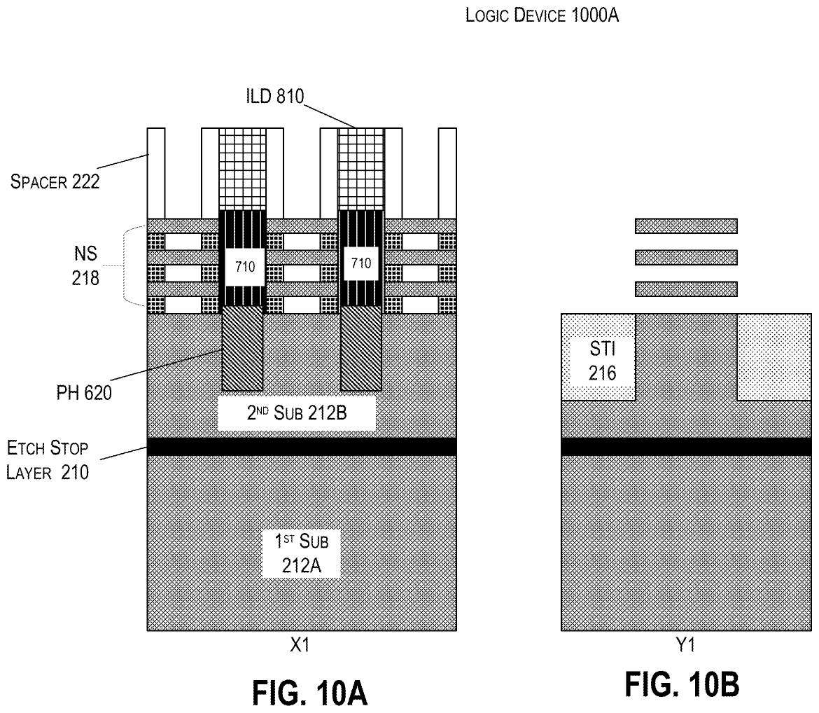

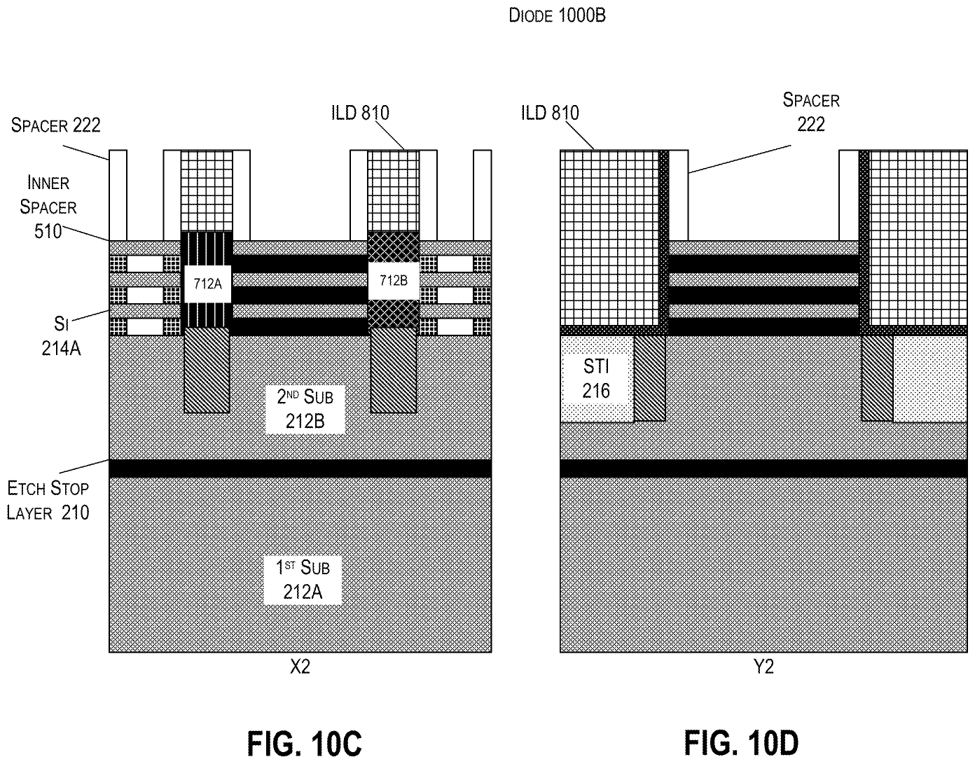

FIGS. 10A-10D illustrate the semiconductor device after, including the logic device 1000A and the diode 1000B, the removal of the silicon germanium layer, in accordance with some embodiments. In some embodiments, the SiGe layer is removed from the vertically stacked epitaxial layers of Si 214A and SiGe 214B in the logic device 1000A and the diode 1000B. However, the protective liner 720, and the N-type doped section 712A and the P-type doped section 712B preserve the SiGe layer of the vertically stacked epitaxial layers of Si 214A and SiGe 214B from removal in the Y1 and Y2 sections of the diode 1000B, which is shown in FIGS. 10C-10D.

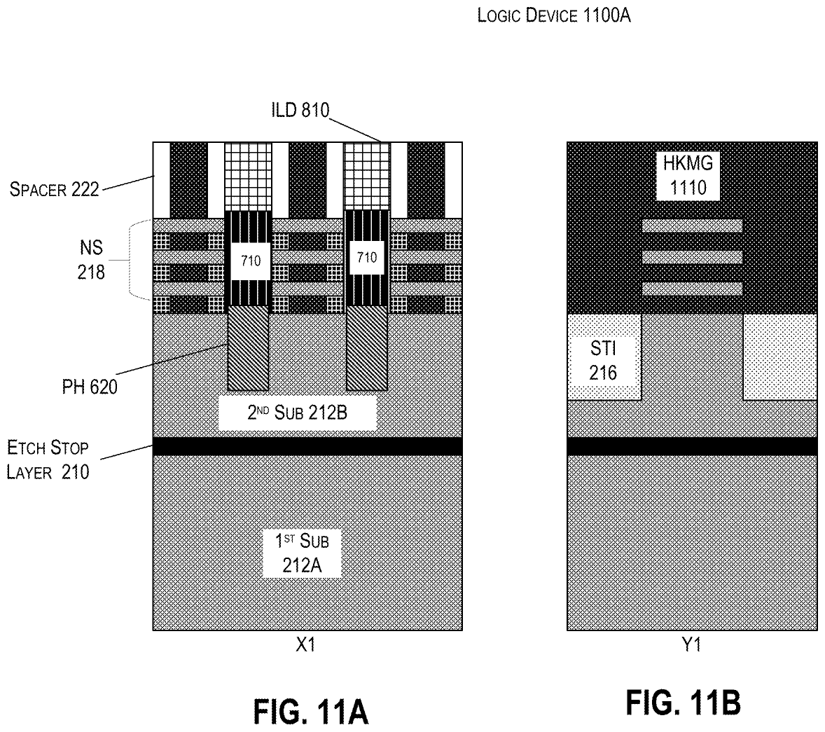

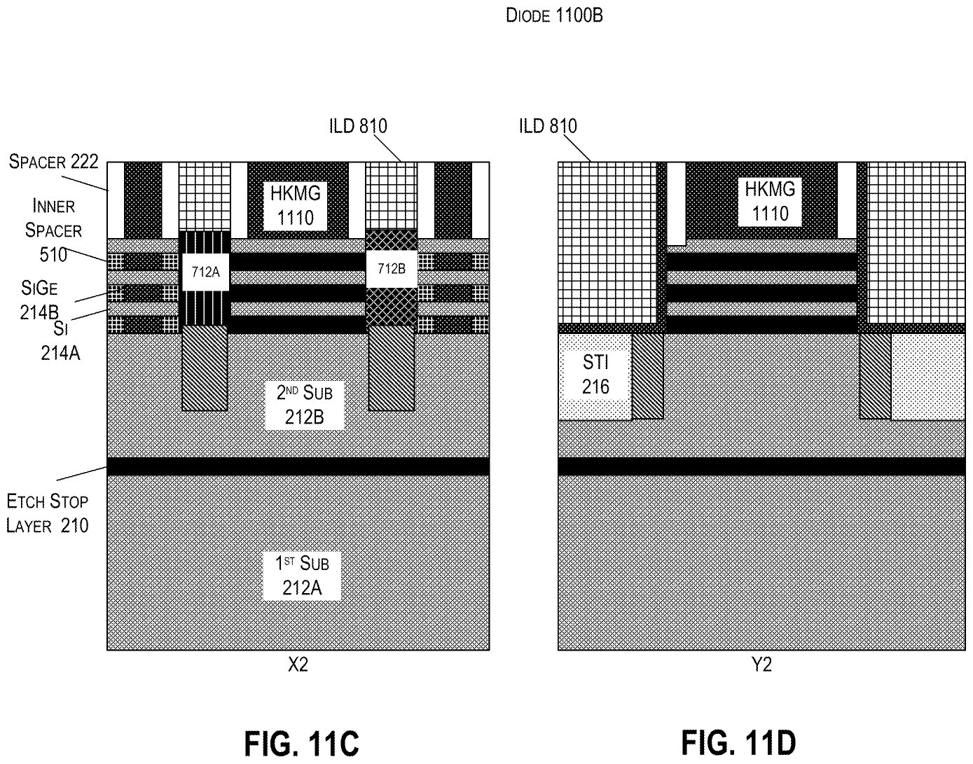

FIGS. 11A-11D illustrate the semiconductor device, including the logic device 1100A and the diode 1100B, after the formation of the replacement metal gate, HKMG 1110, in accordance with some embodiments. In some embodiments, the metal gate materials that are appropriate for the desired threshold voltage and electron behavior of the semiconductor device are formed. A replacement metal gate (RMG) process can be used to fabricate metal gate electrodes, form the contact for source/drains, the gate contact, and the metal gate regions in the N-type doped section 712A and the P-type doped section 712B section. In some embodiments, RMG can involve the replacement of the SiGe with a metal material, which can offer improved electrical performance and scalability. The metal gates can provide electrostatic control of the channel region, reduce leakage currents, and improve the semiconductor device's performance. In some embodiments, the metal gates can further provide improved control over the work function, enable matching of threshold voltages, and reduce semiconductor device variability.

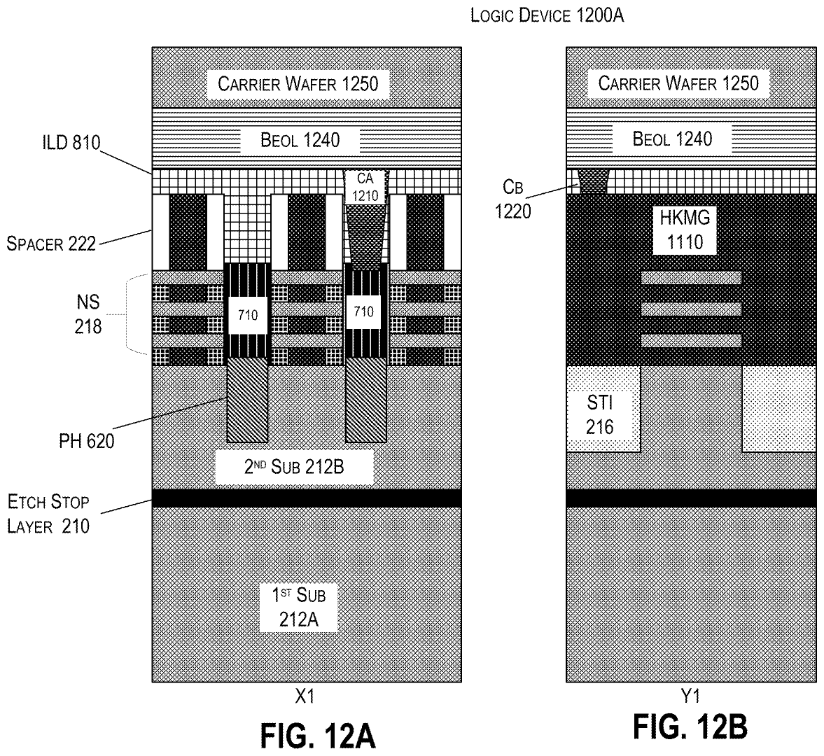

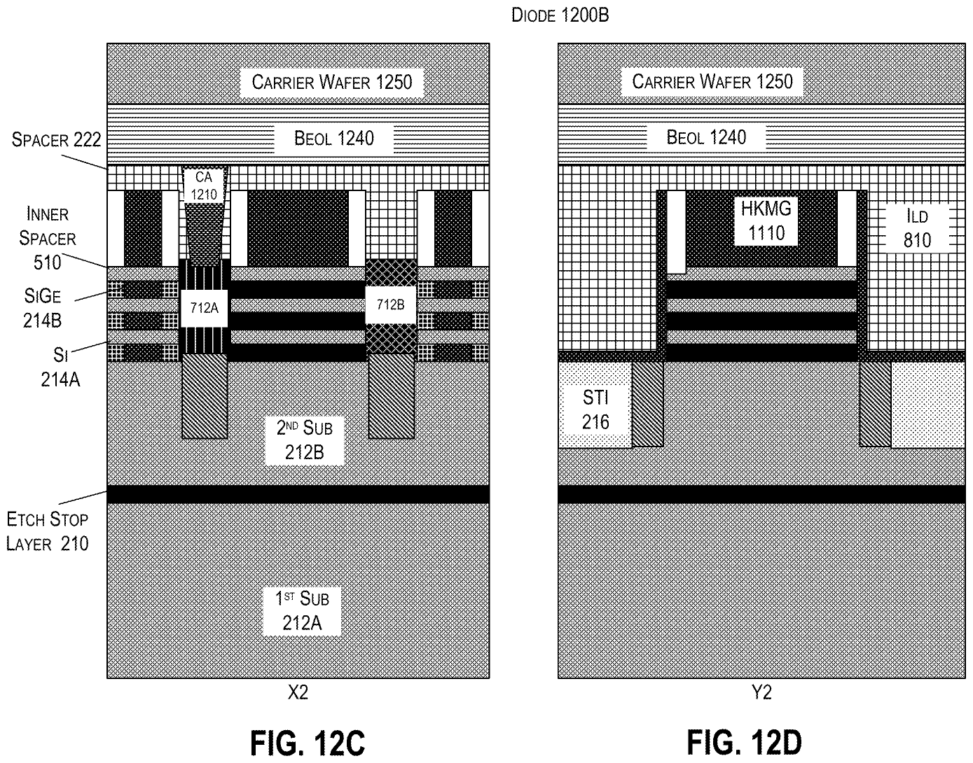

FIGS. 12A-12D illustrate a semiconductor device, including the logic device 1200A and the diode 1200B, after the formation of the middle of line, in accordance with some embodiments. In some embodiments, the middle of line, MOL, is performed. The formation of the MOL involves the formation of the metal layers and interconnects that connect various components and transistors on the semiconductor device. In several embodiments, during the MOL process, multiple metal layers are deposited and patterned on the semiconductor device. These metal layers serve as electrical connections, such as contacts CA 1210, and gate contact, CB 1220, which allow signals to pass between different parts of the integrated circuit. In addition to metal layers, insulating layers (often made of low-k dielectric materials, such as ILD) can be deposited between metal layers to isolate them from each other and prevent electrical interference. In some embodiments, advanced lithography and patterning techniques are used to define the intricate patterns of metal lines and vias (vertical connections between metal layers) during the MOL process. Chemical-mechanical polishing (CMP), which involves the planarization of the semiconductor device's surface after each metal layer deposition, can be performed to ensure a flat and smooth surface for subsequent metal layers. In an embodiment, barrier and liner layers are deposited before the metal layers to enhance adhesion, prevent metal diffusion, and improve overall performance.

In some embodiments, the back end of line, BEOL 1240, is formed over the MOL, followed by formation of the carrier wafer 1250. The BEOL 1240 can include metal interconnects, e.g., wires and metal lines, and insulating layers that connect the various components of the semiconductor device and enable them to function as a cohesive unit.

In various embodiments, carrier wafer bonding, also known as wafer-to-wafer bonding or chip-to-wafer bonding, is performed to join two semiconductor devices together by creating a permanent bond between them. In some embodiments, the two semiconductor devices can be brought into contact and bonded at the atomic or molecular level, to create an interface. In an embodiment, the two semiconductor devices are brought into contact under controlled conditions, such as controlled pressure and temperature, to enable atomic or molecular bonding at the interface. Such bonding can be done at room temperature or with elevated temperatures. Alternatively, in some embodiments, an electric field and elevated temperature are utilized to create a bond. One semiconductor device can be made of semiconductor material, while the other can be a glass or silicon dioxide (SiO2) wafer. The electric field can cause ions in the glass or SiO2 to migrate and chemically bond with the semiconductor material in the other semiconductor device. In additional embodiments, a thin metal layer or metal alloy can be used as an intermediate bonding layer between the semiconductor devices. The metal layer can be deposited or transferred onto one or both semiconductor device surfaces, and the semiconductor devices can then be brought into contact and subjected to temperature and pressure to create a metallic bond.

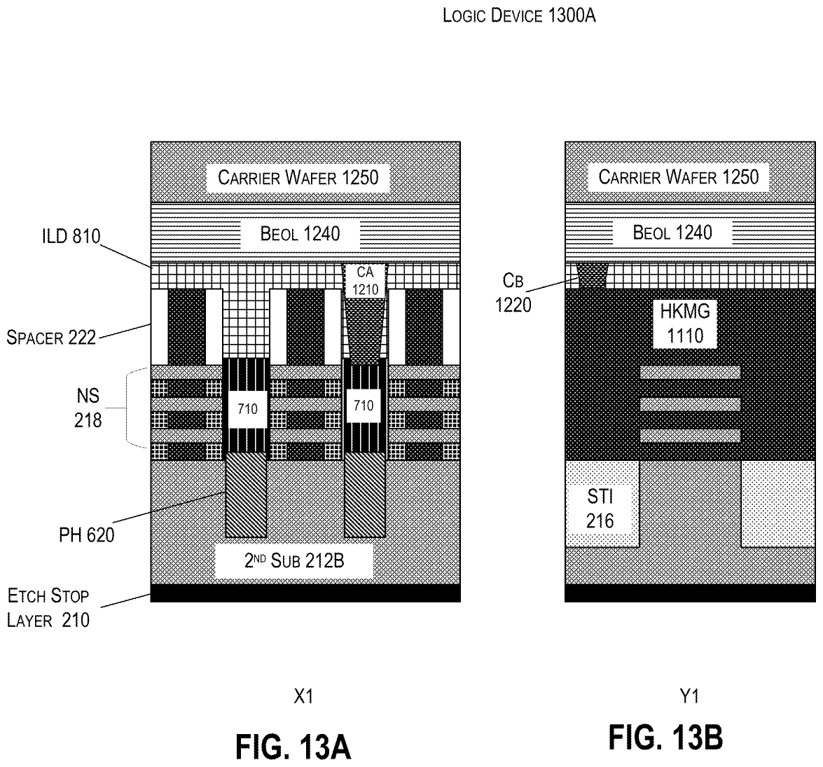

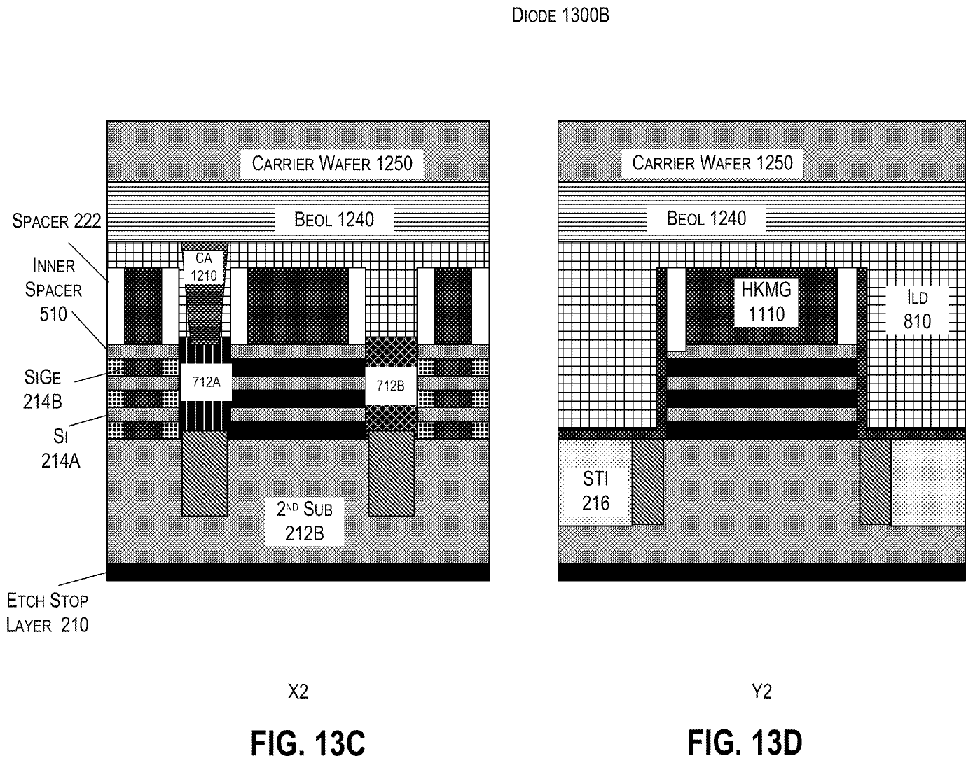

FIGS. 13A-13D illustrate a semiconductor device, including the logic device 1300A and the diode 1300B, after the removal of the first substrate, in accordance with some embodiments. In some embodiments, the wafer is flipped, and the first substrate is removed. It should be noted that, for the sake of simplicity, the semiconductor device is not shown as flipped.

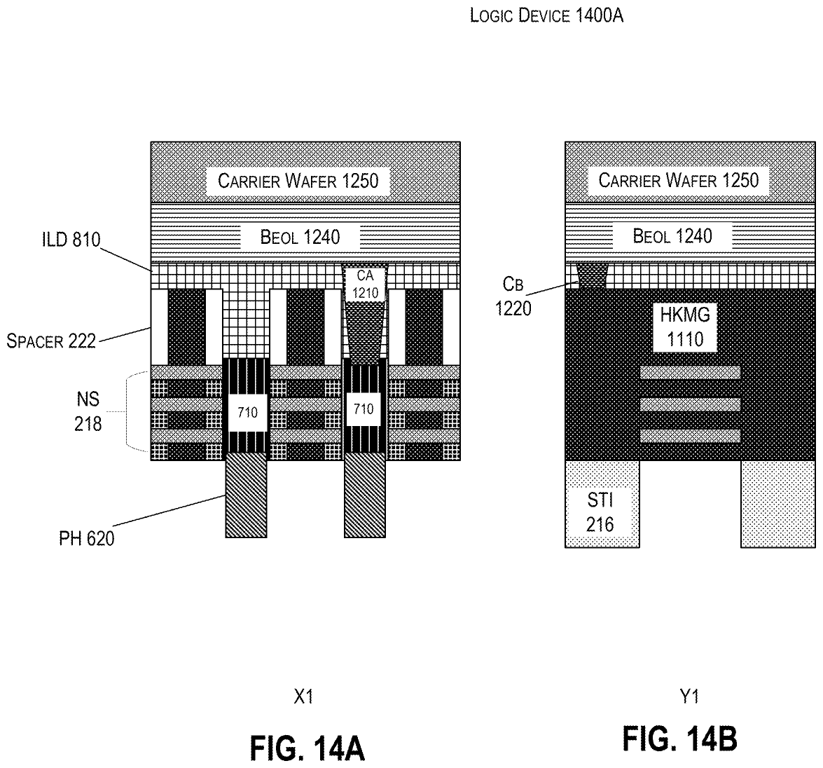

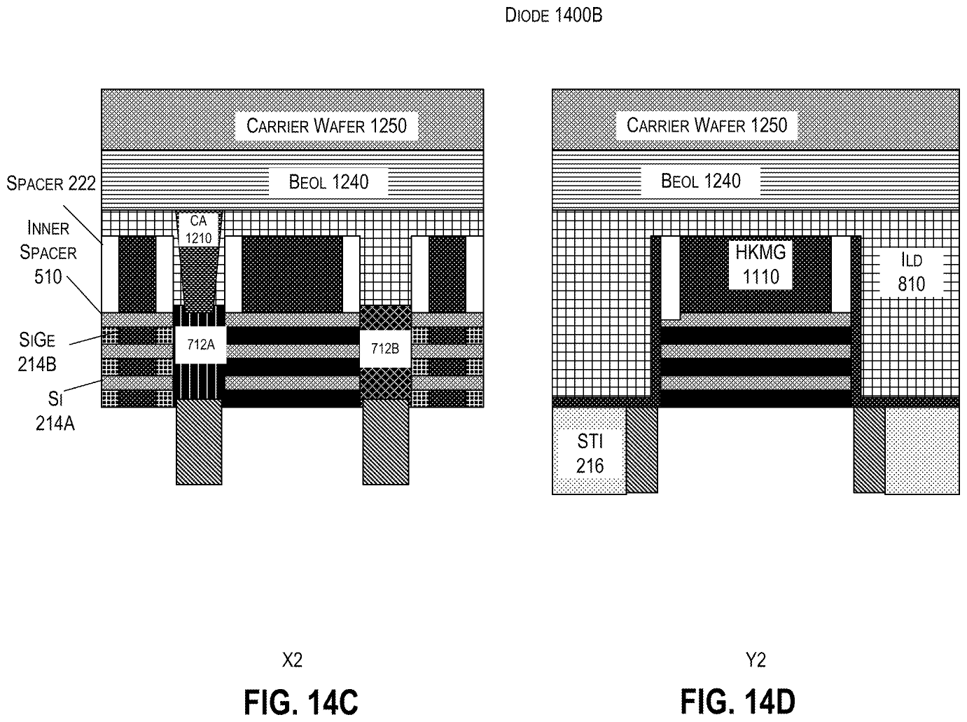

FIGS. 14A-14D illustrate a semiconductor device, including the logic device 1400A and the diode 1400B, after the removal of the etch stop layer, in accordance with some embodiments. In some embodiments, the etch stop layer and the second substrate are removed.

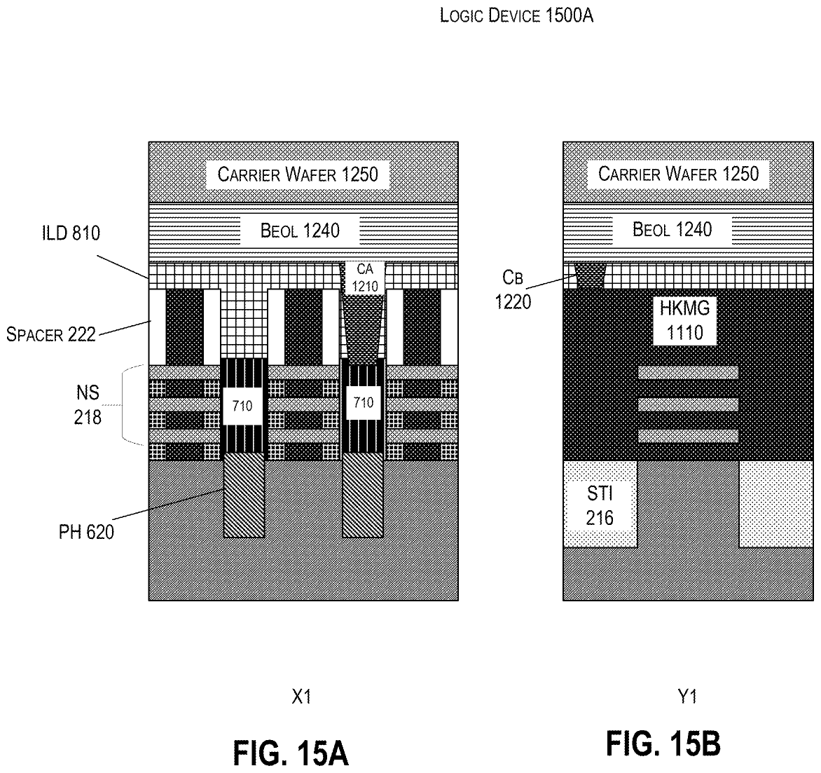

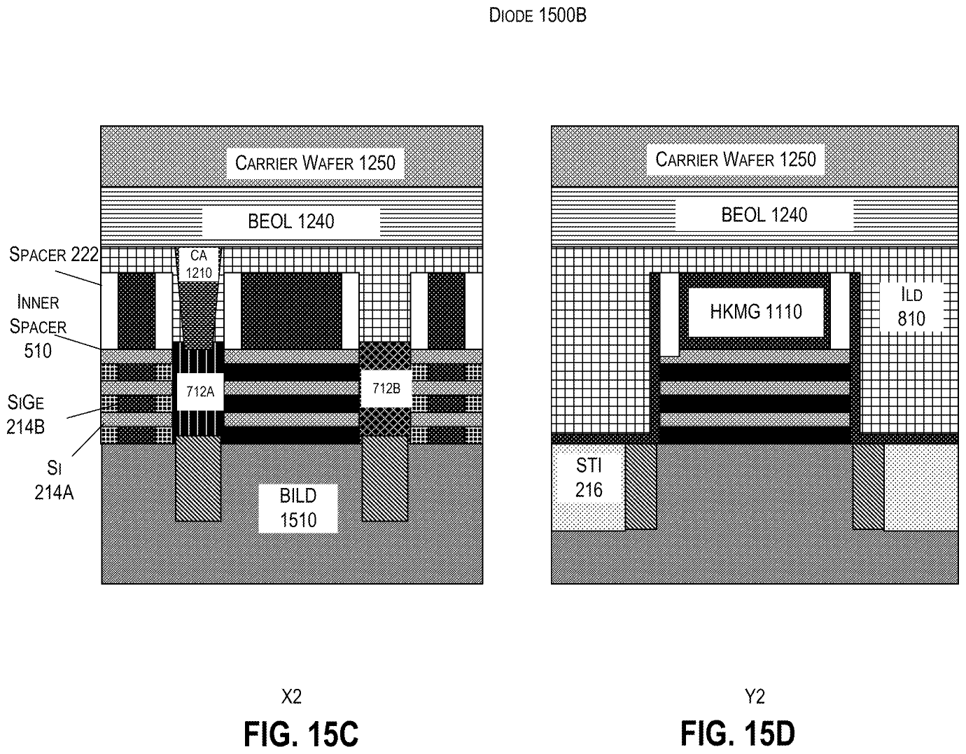

FIGS. 15A-15D illustrate a semiconductor device, including the logic device 1500A and the diode 1500B, after the formation of the backside interlayer dielectric, in accordance with some embodiments. In some embodiments, the backside dielectric, BILD 1510 is formed below the vertically stacked epitaxial layers of Si 214A and SiGe 214B and surrounds the placeholders 620 and the STI 216. The BILD 1510 can be an insulating material or layer used to isolate and provide electrical insulation between the semiconductor device's active regions and the placeholders 620. In various embodiments, the BILD 1510 can function as a protective layer, shielding the active regions of the semiconductor device from external contaminants, moisture, and mechanical stress. The BILD 1510 can further help prevent physical damage, such as scratches or particle contamination, which could adversely affect semiconductor device performance. Additionally, the BILD 1510 can function as a barrier against moisture ingress, which can cause corrosion and degradation of the semiconductor device's components. The first substrate and the second substrate can be removed by an RIE process.

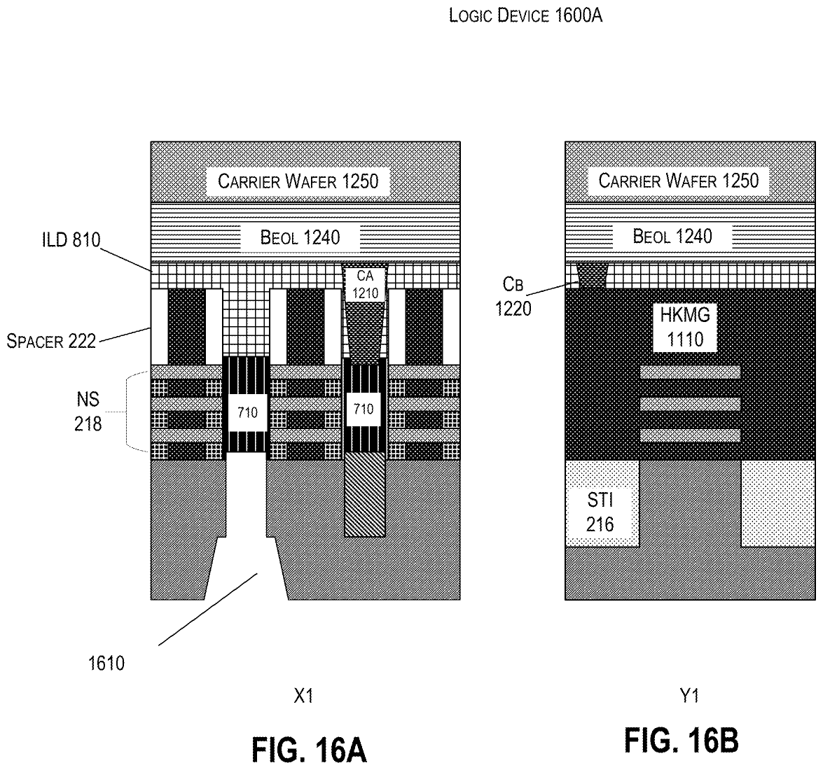

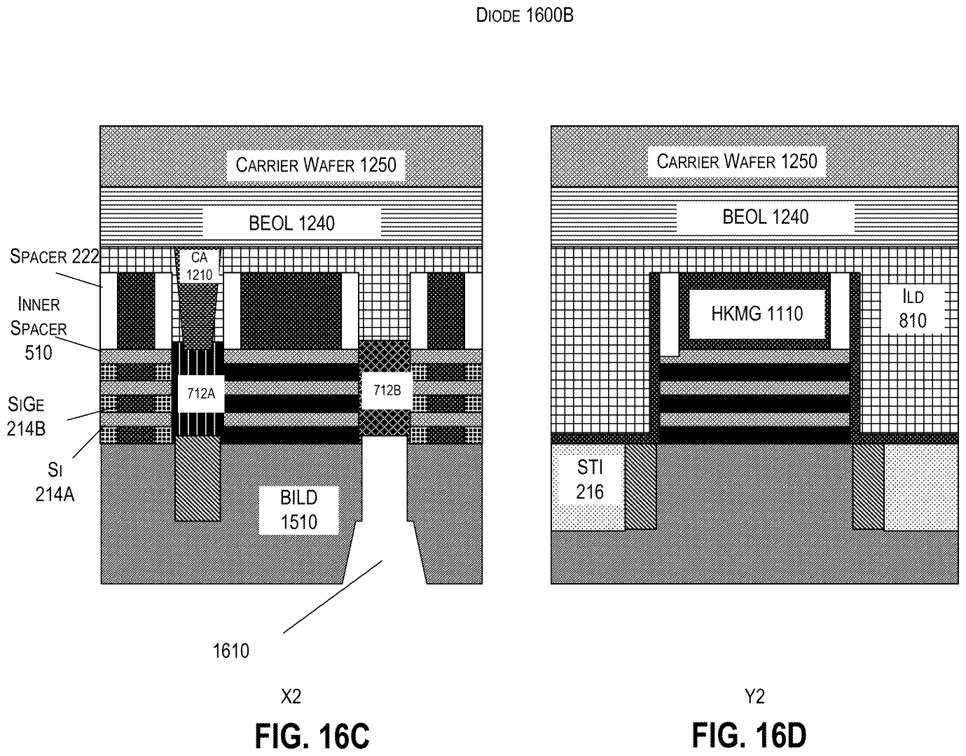

FIGS. 16A-16D illustrate a semiconductor device, including the logic device 1600A and the diode 1600B, after the patterning of the backside contact, in accordance with some embodiments. In some embodiments, a sacrificial placeholder is removed so that a recess 1610 is formed that exposes the bottom of a source/drain region and a either the N-type doped section 712A or the P-type doped section 712B.

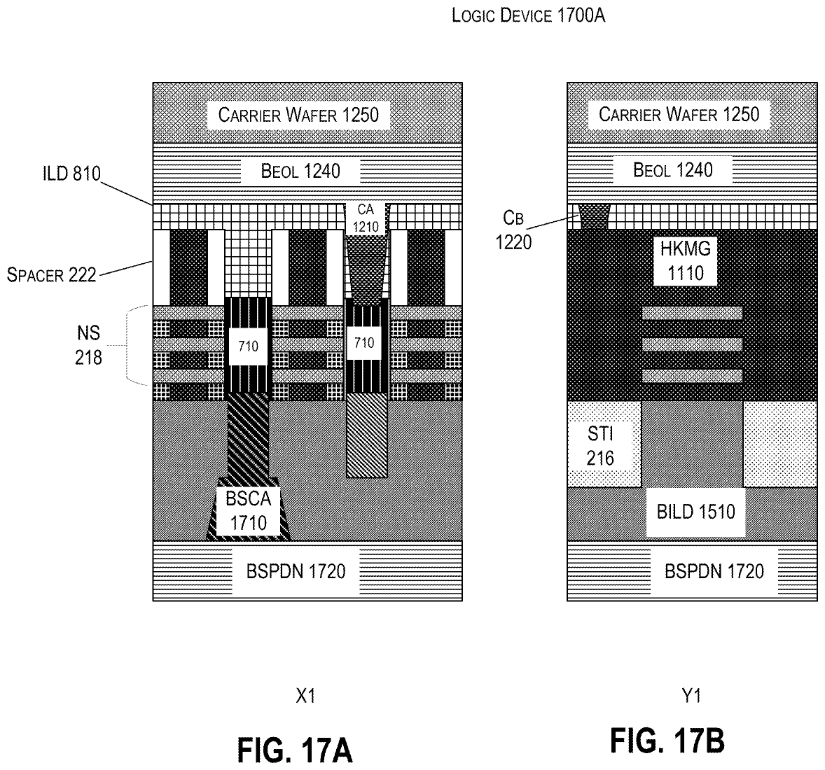

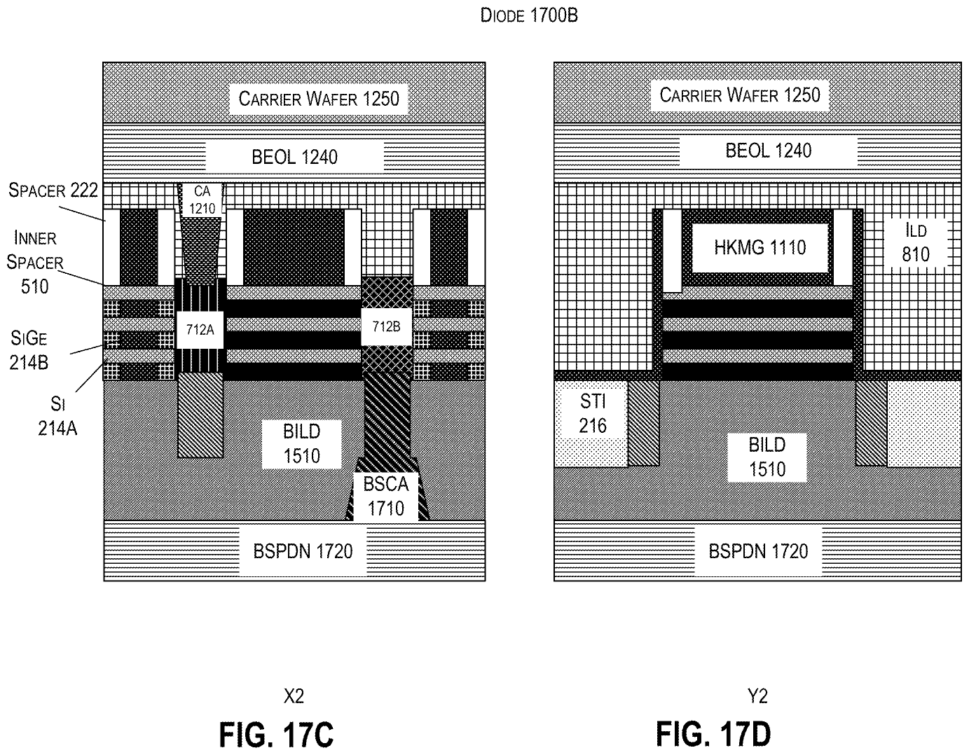

FIGS. 17A-17D illustrate a semiconductor device, including the logic device 1700A and the diode 1700B, after the formation of the backside contact, in accordance with some embodiments. In some embodiments, the backside contact, BSCA 1710 is formed within the recess by filling it with a metal contact. The BSCA 1710 is surrounded by the BILD 1510. A backside interconnect 1720 is formed to cover the BSCA 1710 and the BILD 1510. The backside interconnect 1720 can be used to connect the semiconductor device to other devices.

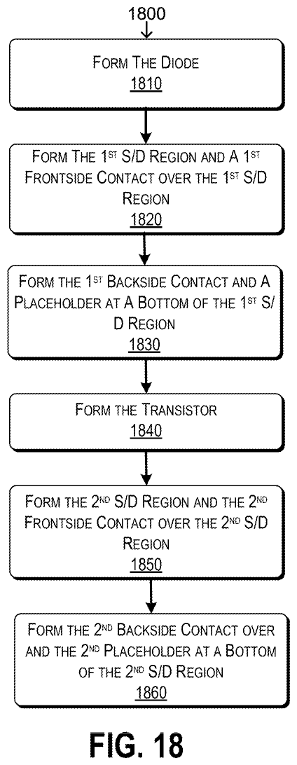

FIG. 18 illustrates a block diagram of a method 1800 for forming the semiconductor device, in accordance with some embodiments. As shown by block 1810, the diode is formed.

As shown in block 1820, as part of forming the diode, a first source/drain region and a first frontside contact over the first source/drain region are formed.

As shown in block 1830, as part of forming the diode, a first backside contact, and a placeholder at a bottom surface of the first source/drain region are formed.

As shown in block 1840, a transistor is formed.

As shown in block 1850, as part of forming the transistor, a second source/drain region and a second frontside contact over the second source/drain region are formed.

As shown in block 1860, as part of forming the transistor, a second backside contact and a second placeholder at a bottom surface of the second source/drain region are formed.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a diode, the diode comprising:
a first frontside contact over a first source/drain region;
a first backside contact; and
a first placeholder connected to a bottom surface of the first source/drain region.

2. The semiconductor device of claim 1, further comprising a transistor, the transistor comprising:
a second frontside contact over a second source/drain region;
a second backside contact; and
a second placeholder connected to a bottom surface of the second source/drain region.

3. The semiconductor device of claim 2, wherein the diode is an electrostatic discharge (ESD) diode.

4. The semiconductor device of claim 2, wherein the transistor includes a plurality of nanosheet gates.

5. The semiconductor device of claim 1, wherein the diode further includes:
a third source/drain region; and
alternative layers of silicon and silicon germanium extended horizontally between the first source/drain region and the third source/drain region.

6. The semiconductor device of claim 5, wherein the first source/drain region is an N-type source-drain region and the third source/drain region is a P-type source/drain region, or the first source/drain region is a P-type source-drain region and the third source/drain region is an N-type source/drain region.

7. The semiconductor device of claim 5, wherein the diode further comprises:
shallow trench isolation (STI);
one or more additional placeholders; and
a protective liner over the STI, the one or more additional placeholders, portions of the diode that are not in direct contact with the first source/drain region, and the third source/drain region.

8. The semiconductor device of claim 7, wherein the protective liner is made of silicon nitride.

9. The semiconductor device of claim 2, wherein:
the diode is adjacent the transistor; and
the diode and the transistor are separated by a dummy gate by an inner spacer.

10. A semiconductor device, comprising:
a diode, the diode comprising:
a first frontside contact over a first source/drain region; and
a first placeholder connected to a bottom surface of the first source/drain region, and
a logic device including a logic backside contact and a logic frontside contact.

11. The semiconductor device of claim 10, wherein:
the diode is an electrostatic discharge (ESD) diode; and
the logic device is a nanosheet transistor.

12. The semiconductor device of claim 10, wherein the diode further comprises:
a second source/drain region; and
alternative layers of silicon and silicon germanium extended horizontally between the first source/drain region and the second source/drain region.

13. The semiconductor device of claim 12, wherein:
the first source/drain region is an N-type source-drain region and the second source/drain region is a P-type source/drain region; or
the first source/drain region is a P-type source-drain region and the second source/drain region is an N-type source/drain region.

14. The semiconductor device of claim 12, wherein the diode further comprises:
shallow trench isolation (STI);
one or more additional placeholders; and
a protective liner over the STI, the one or more additional placeholders, and portions of the diode that are not in direct contact with the first source/drain region and the second source/drain region.

15. The semiconductor device of claim 10, wherein the diode is adjacent the logic device, wherein the diode and the logic device are separated by a dummy gate by an inner spacer.

16. A method for forming a semiconductor device, the method comprising:
forming a diode, comprising:
forming a first source/drain region;
forming a first frontside contact over the first source/drain region;
forming a first backside contact; and
forming a placeholder at a bottom surface of the first source/drain region.

17. The method of claim 16, further comprising:
forming a transistor, comprising:
forming a second source/drain region;
forming a second frontside contact over the second source/drain region;
forming a second backside contact; and
forming a second placeholder at a bottom surface of the second source/drain region.

18. The method of claim 17, further comprising forming a plurality of nanosheet gates extended horizontally along gate channels.

19. The method of claim 16, further comprising:
forming a third source/drain region; and
forming alternative layers of silicon and silicon germanium extended horizontally between the first source/drain region and the third source/drain region.

20. The method of claim 19, further comprising:
forming shallow trench isolation (STI);
forming one or more additional placeholders; and
forming a protective liner over the STI, the one or more additional placeholders, and portions of the diode that are not in direct contact with the first source/drain region and the third source/drain region.

21. The method of claim 17, further comprising isolating the diode and the transistor by a dummy gate by an inner spacer.

22. A method for forming a semiconductor device, the method comprising:
forming a diode, comprising:
forming a first source/drain region;
forming a first frontside contact over the first source/drain region; and
a first placeholder connected to a bottom surface of the first source/drain region, and
forming a logic device, comprising:
forming a logic backside contact; and
forming a logic frontside contact.

23. The method of claim 22, further comprising:
forming a second source/drain region; and
forming alternative layers of silicon and silicon germanium extended horizontally between the first source/drain region and the second source/drain region.

24. The method of claim 23, further comprising:
forming shallow trench isolation (STI);
forming one or more additional placeholders; and
forming a protective liner over the STI, the one or more additional placeholders, and portions of the diode that are not in direct contact with the first source/drain region and the second source/drain region.

25. The method of claim 22, further comprising isolating the diode and the logic device by a dummy gate by an inner spacer.
